(19) United States
(12) Patent Application Publication
(10) Pub. No.: US 2025/0374699 A1
(43) Pub. Date: Dec. 4, 2025

(54) PHOTOELECTRIC CONVERSION APPARATUS, PHOTOELECTRIC CONVERSION SYSTEM, MOVABLE BODY, AND EQUIPMENT

(71) Applicant: CANON KABUSHIKI KAISHA, Tokyo (JP)

(72) Inventors: YOSHIKI KATO, Kanagawa (JP); TAIKAN KANOU, Kanagawa (JP); KOSEI UEHIRA, Tokyo (JP); ALICE MORIMOTO, Kanagawa (JP)

(21) Appl. No.: 19/216,492

(22) Filed: May 22, 2025

(30) Foreign Application Priority Data
May 29, 2024 (JP) 2024-087054

(51) Int. Cl. H10F 39/00; G01S 7/481; G01S 17/931; H10F 30/225

(52) U.S. Cl. CPC H10F 39/807; G01S 7/4816; G01S 17/931; H10F 30/225; H10F 39/028; H10F 39/811

(57) ABSTRACT

A photoelectric conversion apparatus includes a semiconductor layer including an avalanche photodiode. The avalanche photodiode includes a first semiconductor region provided at a first depth position, a second semiconductor region located closer to the second surface than the first semiconductor region, a third semiconductor region that is located closer to the second surface than the second semiconductor region, is in contact with a contact plug to which a first voltage is applied, and is provided to a second depth position, a region that is in contact with a contact plug to which a second voltage is applied and provided to a third depth position, and a fourth semiconductor region provided between the region and the third semiconductor region. The photoelectric conversion apparatus includes a dielectric member including at least a portion located on a portion overlapping the fourth semiconductor region and extending over the third depth position.

### BACKGROUND

### Technical Field

The present disclosure relates to a photoelectric conversion apparatus, a photoelectric conversion system, a movable body, and equipment.

### Description of the Related Art

A photoelectric conversion apparatus that uses an avalanche photodiode with avalanche multiplication has recently been proposed.

Japanese Patent Application Laid-Open No. 2018-64086 discusses a configuration including a plurality of pixels each including an avalanche photodiode. To each of the avalanche photodiodes in the respective pixels, a high reverse bias voltage is applied.

In a case where the area of each pixel is decreased so as to improve the resolution in each pixel including the avalanche photodiode discussed in Japanese Patent Application Laid-Open No. 2018-64086, the distance between an anode region and a cathode region in the avalanche photodiode is decreased, which leads to an increase in leakage current between the anode region and the cathode region.

### SUMMARY

According to an aspect of the present disclosure, a photoelectric conversion apparatus includes a semiconductor layer including an avalanche photodiode configured to perform an avalanche multiplication operation by a first voltage and a second voltage to be applied, and a first surface on which light is incident and a second surface opposed to the first surface. The avalanche photodiode includes a first semiconductor region of a first conductivity type provided at a first depth position as viewed from the second surface in the semiconductor layer, a second semiconductor region of a second conductivity type located closer to the second surface than the first semiconductor region, a third semiconductor region of the first conductivity type located closer to the second surface than the second semiconductor region, in contact with a contact plug to which the first voltage is applied, and provided to a second depth position in depth from the second surface, a region of a semiconductor region of the second conductivity type, in contact with a contact plug to which the second voltage is applied, and provided to a third depth position in depth from the second surface, and a fourth semiconductor region of the first conductivity type provided between the region and the third semiconductor region. The photoelectric conversion apparatus includes a dielectric material including at least a portion extending from the second surface to an inside of the semiconductor layer, and being located on a portion overlapping at least the fourth semiconductor region in a planar view with respect to the second surface. The portion extending from the second surface to an inside of the semiconductor layer extends over the third depth position from the second surface.

Further features of the present disclosure will become apparent from the following description of exemplary embodiments with reference to the attached drawings.

### BRIEF DESCRIPTION OF THE DRAWINGS

FIG. 1 is an overall view of a photoelectric conversion apparatus.

FIG. 2 is an overall view of a sensor substrate.

FIG. 3 is an overall view of a circuit substrate.

FIG. 4 is a circuit diagram illustrating a configuration example of a pixel circuit.

FIGS. 5A to 5C each schematically illustrate a relationship between an operation of an avalanche photodiode (APD) and an output signal.

FIG. 6 is a sectional view of the photoelectric conversion apparatus according to a first exemplary embodiment.

FIG. 7 is a plan view of the photoelectric conversion apparatus according to the first exemplary embodiment.

FIGS. 8A to 8F illustrate processes for a manufacturing method of the photoelectric conversion apparatus according to the first exemplary embodiment.

FIG. 9 is a plan view of a photoelectric conversion apparatus according to a second exemplary embodiment.

FIG. 10 is a plan view of the photoelectric conversion apparatus according to the second exemplary embodiment.

FIG. 11 is a plan view of the photoelectric conversion apparatus according to the second exemplary embodiment.

FIG. 12 is a plan view of the photoelectric conversion apparatus according to the second exemplary embodiment.

FIG. 13 is a plan view of the photoelectric conversion apparatus according to the second exemplary embodiment.

FIG. 14 is a plan view of the photoelectric conversion apparatus according to the second exemplary embodiment.

FIG. 15 is a plan view of the photoelectric conversion apparatus according to the second exemplary embodiment.

FIG. 16 is a plan view of the photoelectric conversion apparatus according to the second exemplary embodiment.

FIG. 17 is a sectional view of a photoelectric conversion apparatus according to a third exemplary embodiment.

FIG. 18 is a plan view of the photoelectric conversion apparatus according to the third exemplary embodiment.

FIGS. 19A to 19G illustrate processes for a manufacturing method of the photoelectric conversion apparatus according to the third exemplary embodiment.

FIG. 20 is a sectional view of a photoelectric conversion apparatus according to a fourth exemplary embodiment.

FIG. 21 is a plan view of the photoelectric conversion apparatus according to the fourth exemplary embodiment.

FIG. 22 is a sectional view of a photoelectric conversion apparatus according to a fifth exemplary embodiment.

FIG. 23 is a sectional view of a photoelectric conversion apparatus according to a sixth exemplary embodiment.

FIG. 24 is a sectional view of a photoelectric conversion apparatus according to a seventh exemplary embodiment.

FIG. 25 is a plan view of a photoelectric conversion apparatus according to an eighth exemplary embodiment.

FIG. 26 is a plan view of the photoelectric conversion apparatus according to the eighth exemplary embodiment.

FIG. 27 is a sectional view of a photoelectric conversion apparatus according to a ninth exemplary embodiment.

FIG. 28 is a plan view of the photoelectric conversion apparatus according to the ninth exemplary embodiment.

FIG. 29 is a plan view of the photoelectric conversion apparatus according to the ninth exemplary embodiment.

FIG. 30 is a sectional view of a photoelectric conversion apparatus according to a tenth exemplary embodiment.

FIG. 31 is a plan view of the photoelectric conversion apparatus according to the tenth exemplary embodiment.

FIG. 32 is a sectional view of the photoelectric conversion apparatus according to the tenth exemplary embodiment.

FIG. 33 is a sectional view of the photoelectric conversion apparatus according to the tenth exemplary embodiment.

FIG. 34 is a sectional view of the photoelectric conversion apparatus according to the tenth exemplary embodiment.

FIG. 35 is a sectional view of a photoelectric conversion apparatus according to an eleventh exemplary embodiment.

FIG. 36 is a plan view of the photoelectric conversion apparatus according to the eleventh exemplary embodiment.

FIG. 37 is a graph illustrating an impurity concentration of a semiconductor region of the photoelectric conversion apparatus according to the first exemplary embodiment.

FIGS. 38A to 38C each illustrate a configuration example of equipment.

FIG. 39 illustrates a configuration example of equipment.

### DESCRIPTION OF THE EMBODIMENTS

Exemplary embodiments will be described below with reference to the drawings.

The following exemplary embodiments will mainly describe an image capturing apparatus serving as an example of a photoelectric conversion apparatus. However, the exemplary embodiments are not limited only to an image capturing apparatus and can also be applied to other examples of the photoelectric conversion apparatus. The other examples of the photoelectric conversion apparatus include a ranging apparatus (e.g., an apparatus for measuring a distance or the like using focus detection or time of flight (ToF)) and a photometric apparatus (e.g., an apparatus for measuring the amount of incident light).

Semiconductor regions, a conductivity type of a well, and an implanted dopant to be described in the following exemplary embodiments are merely examples, and are not limited only to the conductivity types and the dopant described in the exemplary embodiments. The conductivity types and the dopant described in the exemplary embodiments can be appropriately changed, and the potential of each of the semiconductor regions and the well can be changed appropriately according to the change.

The conductivity types of transistors described in the following exemplary embodiments are merely examples, and are not limited only to the conductivity types described in the exemplary embodiments. The conductivity types described in the exemplary embodiments can be changed as appropriate. A potential at the gate, source, and drain of each transistor can be changed appropriately according to the change.

For example, in a case of a transistor that is operated as a switch, a low level and a high level of a potential to be supplied to the gate of the transistor can be reversed with respect to the ones described in the exemplary embodiments according to the change of the conductivity types. The conductivity types of the semiconductor regions described in the following exemplary embodiments are also merely examples and are not limited only to the conductivity types described in the exemplary embodiments. The conductivity types described in the exemplary embodiments can be appropriately changed and the potentials of the semiconductor regions can be appropriately changed according to the change of the conductivity types. An impurity concentration described in the following exemplary embodiments indicates an effective impurity concentration unless otherwise noted. In a semiconductor region in which a donor and an acceptor coexist, the impurity concentration corresponding to the difference between the donor and the acceptor is described based on effective characteristics of the semiconductor region.

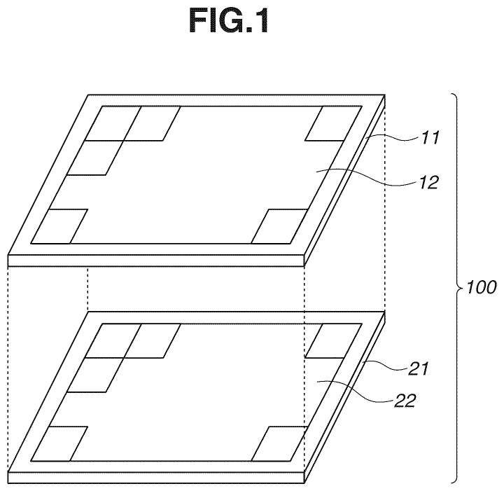

FIG. 1 illustrates a configuration example of a stacked photoelectric conversion apparatus 100 according to a first exemplary embodiment of the present disclosure.

The photoelectric conversion apparatus 100 is a structure in which two substrates, e.g., a sensor substrate 11 (one substrate) and a circuit substrate 21 (another substrate), are stacked. The sensor substrate 11 and the circuit substrate 21 are electrically connected, thereby forming the photoelectric conversion apparatus 100. The sensor substrate 11 includes a first semiconductor layer having a photoelectric conversion element 102 to be described below, and a first wiring structure. The circuit substrate 21 includes a second semiconductor layer having circuits such as a signal processing unit 103 to be described below, and a second wiring structure. The photoelectric conversion apparatus 100 has a structure in which the second semiconductor layer, the second wiring structure, the first wiring structure, and the first semiconductor layer are stacked in this order. The photoelectric conversion apparatus 100 according to each exemplary embodiment is a back-illuminated photoelectric conversion apparatus having a structure in which light enters from a first surface and the circuit substrate 21 is provided on a second surface.

In the following description, assume that the sensor substrate 11 and the circuit substrate 21 are diced chips, but are not limited to chips. For example, the sensor substrate 11 and the circuit substrate 21 can also be a wafer. The sensor substrate 11 and the circuit substrate 21 can also be diced after being stacked in a wafer state, or chips can be stacked and bonded after being formed into chips.

The sensor substrate 11 is provided with a pixel region 12, and the circuit substrate 21 is provided with a circuit region 22 for processing signals detected in the pixel region 12.

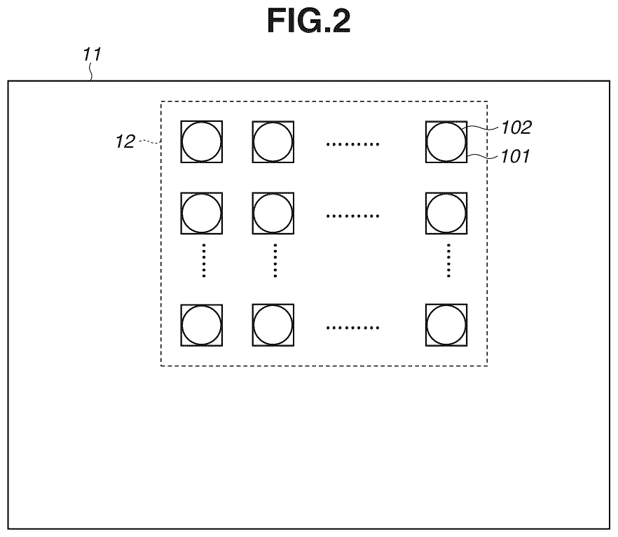

FIG. 2 illustrates a layout example of the sensor substrate 11. Pixels 101 each including the photoelectric conversion element 102 including an avalanche photodiode (APD) are arranged in a two-dimensional array in a planar view and form the pixel region 12.

The pixels 101 are typically pixels for forming an image. However, in a case where the pixels 101 are used for ToF, the pixels 101 need not necessarily form an image. In other words, the pixels 101 can be pixels for measuring the amount of light and time when light arrives.

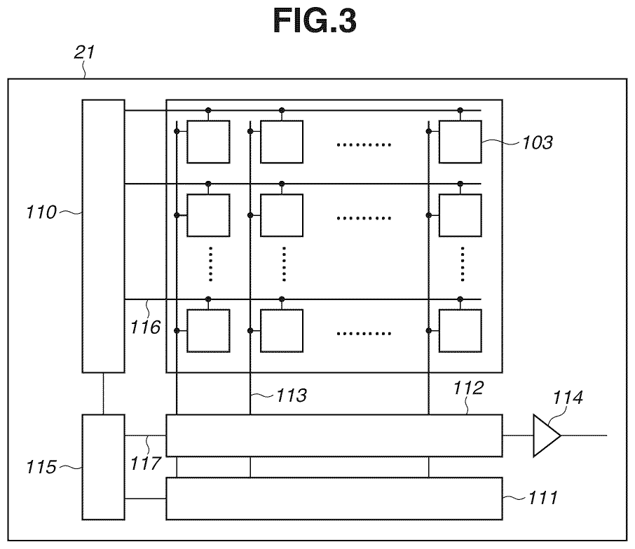

FIG. 3 illustrates a configuration example of the circuit substrate 21. The circuit substrate 21 includes a signal processing unit 103 for processing electric charges photoelectrically converted by the photoelectric conversion element 102 illustrated in FIG. 2, a readout circuit 112, a control pulse generation unit 115, a horizontal scanning circuit unit 111, signal lines 113, and a vertical scanning circuit unit 110.

The photoelectric conversion element 102 illustrated in FIG. 2 and the signal processing unit 103 illustrated in FIG. 3 are electrically connected via a connection line provided for each pixel.

The vertical scanning circuit unit 110 receives a control pulse supplied from the control pulse generation unit 115, and supplies the control pulse to each pixel 101. A logic circuit such as a shift register or an address decoder is used as the vertical scanning circuit unit 110.

A signal output from the photoelectric conversion element 102 in each pixel 101 is processed by the signal processing unit 103. The signal processing unit 103 is provided with a counter, a memory, and the like, and the memory holds digital values.

The horizontal scanning circuit unit 111 inputs control pulses for sequentially selecting columns to the signal processing units 103 so as to read out signals from the memories of the pixels 101 in which digital signals are held.

Signals from the signal processing units 103 in the pixels 101 selected by the vertical scanning circuit unit 110 in the selected column are output to the corresponding signal line 113.

The signals output to the signal line 113 are output to an external recording unit or signal processing unit of the photoelectric conversion apparatus 100 via an output circuit 114.

In the example illustrated in FIG. 2, the photoelectric conversion elements 102 in the pixel region 12 can be one-dimensionally arranged. Even if the number of pixels 101 is one, the advantageous effects of the present disclosure can be obtained, and such a case is also included in the present disclosure. Not every photoelectric conversion element 102 may have the function of the signal processing unit. For example, one signal processing unit can be shared by a plurality of photoelectric conversion elements 102, and signal processing can be sequentially performed.

As illustrated in FIGS. 2 and 3, a plurality of signal processing units 103 is arranged in a region overlapping the pixel region 12 in a planar view. The vertical scanning circuit unit 110, the horizontal scanning circuit unit 111, the readout circuit 112, the output circuit 114, and the control pulse generation unit 115 are arranged overlapping, in a planar view, the region defined by the ends of the sensor substrate 11 and the ends of the pixel region 12. In other words, the sensor substrate 11 includes the pixel region 12 and a non-pixel region located around the pixel region 12. The vertical scanning circuit unit 110, the horizontal scanning circuit unit 111, the readout circuit 112, output circuit 114, and the control pulse generation unit 115 are arranged in a region overlapping the non-pixel region in a planar view.

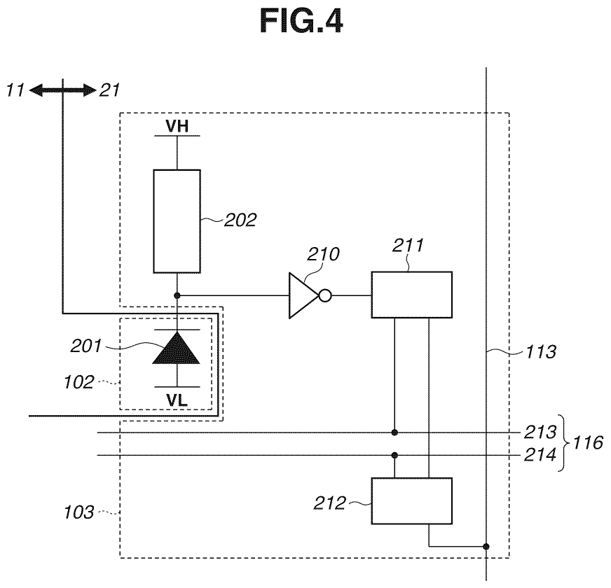

FIG. 4 is a block diagram illustrating a configuration example of equivalent circuits illustrated in FIGS. 2 and 3.

In the example illustrated in FIG. 2, the photoelectric conversion elements 102 each including an APD 201 are provided on the sensor substrate 11, and the other members are provided on the circuit substrate 21.

The APD 201 generates electric charge pairs corresponding to incident light by photoelectric conversion. An anode of the APD 201 is supplied with a voltage VL (second voltage). A cathode of the APD 201 is supplied with a voltage VH (first voltage) that is higher than the voltage VL and supplied to the anode. A reverse bias voltage is supplied to the anode and the cathode such that the APD 201 performs an avalanche multiplication operation. Such a voltage is supplied, and thereby electric charges generated by the incident light cause avalanche multiplication, so that an avalanche current is generated.

In a case where the reverse bias voltage is supplied, the APD 201 has a Geiger mode in which the APD 201 operates in a state where the potential difference between the anode and the cathode of the APD 201 is higher than a breakdown voltage, and a linear mode in which the APD 201 operates in a state where the potential difference between the anode and the cathode of the APD 201 is close to the breakdown voltage or equal to or lower than the breakdown voltage.

The APD 201 that operates in the Geiger mode is referred to as a single-photon avalanche diode (SPAD). For example, the voltage VL (second voltage) is −30 V (volts) and the voltage VH (first voltage) is 1 V. The APD 201 can be operated in the linear mode, or can be operated in the Geiger mode. A potential difference of the SPAD becomes larger and a withstand voltage effect of the SPAD becomes more prominent as compared with the case of an APD in the linear mode, and thereby the SPAD is suitably used.

A quench element 202 is connected to the APD 201 and a power supply that supplies the voltage VH. The quench element 202 functions as a load circuit (quench circuit) during signal multiplication caused by avalanche multiplication and has a function of suppressing a voltage to be supplied to the APD 201 and suppressing avalanche multiplication (quench operation). The quench element 202 also has a function of returning the voltage to be supplied to the APD 201 to the voltage VH by causing a current corresponding to a voltage drop due to the quench operation to flow (recharging operation).

The signal processing unit 103 includes a waveform shaping unit 210, a counter circuit 211, and a selection circuit 212. In the present specification, the signal processing unit 103 may include any one of the waveform shaping unit 210, the counter circuit 211, and the selection circuit 212.

The waveform shaping unit 210 outputs a pulse signal by shaping a potential change of the cathode of the APD 201 that is obtained at the time of photon detection. For example, an inverter circuit is used as the waveform shaping unit 210. While FIG. 4 illustrates an example where one inverter is used as the waveform shaping unit 210, a circuit in which a plurality of inverters is connected in series can also be used, or any other circuit having the waveform shaping effect can be used.

The counter circuit 211 counts the number of pulse signals output from the waveform shaping unit 210, and holds the count value. When a control pulse pRES is supplied via a drive line 213, the number of pulse signals that is held in the counter circuit 211 is reset.

A control pulse pSEL is supplied to the selection circuit 212 from the vertical scanning circuit unit 110 illustrated in FIG. 3 via a drive line 214 illustrated in FIG. 4 (not illustrated in FIG. 3) to switch electric connection and disconnection between the counter circuit 211 and the signal line 113. For example, the selection circuit 212 includes a buffer circuit for outputting a signal.

The electric connection can also be switched by a switch such as a transistor provided between the quench element 202 and the APD 201, or between the photoelectric conversion element 102 and the signal processing unit 103. Similarly, the supply of the voltage VH or the voltage VL to the photoelectric conversion element 102 can be electrically switched using a switch such as a transistor.

The first exemplary embodiment illustrates a configuration that uses the counter circuit 211. Alternatively, the photoelectric conversion apparatus 100 can also acquire a pulse detection timing using a time-to-digital converter (TDC) and a memory in place of the counter circuit 211. In this case, the generation timing of a pulse signal output from the waveform shaping unit 210 is converted into a digital signal by the TDC. To measure the timing of a pulse signal, a control pulse pREF (reference signal) is supplied to the TDC from the vertical scanning circuit unit 110 illustrated in FIG. 3 via a drive line. Based on the control pulse pREF, the TDC acquires a digital signal indicating an input timing of a signal output from each pixel 101 via the waveform shaping unit 210 as a relative time.

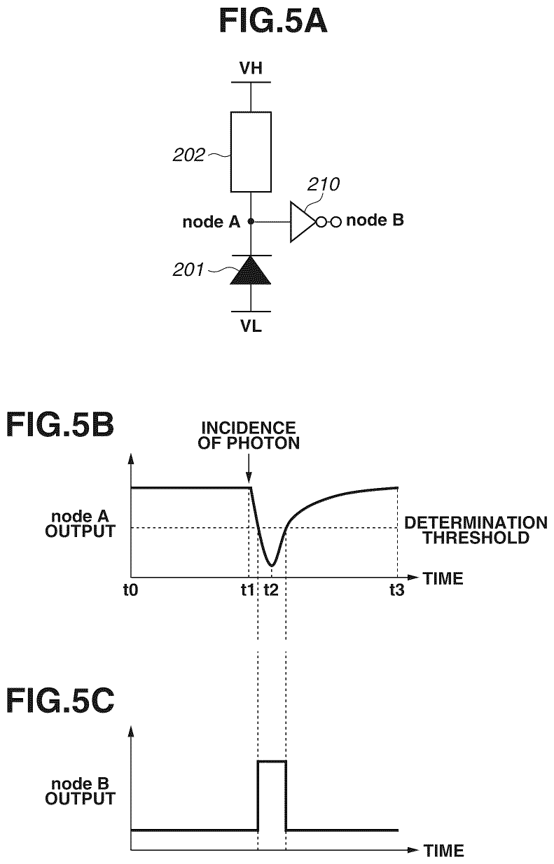

FIGS. 5A to 5C schematically illustrate a relationship between an operation of the APD 201 and an output signal.

FIG. 5A is a circuit diagram illustrating the APD 201, the quench element 202, and the waveform shaping unit 210 in the configuration illustrated in FIG. 4. Assume herein that, in FIG. 5A, a node A corresponds to the input side of the waveform shaping unit 210 and a node B corresponds to the output side of the waveform shaping unit 210. FIG. 5B is a graph illustrating a waveform change at the node A illustrated in FIG. 5A. FIG. 5C is a graph illustrating a waveform change at the node B illustrated in FIG. 5A.

During the period from time t0 to time t1, a potential difference VH-VL is applied to the APD 201 illustrated in FIG. 5A. When a photon is incident on the APD 201 at time t1, avalanche multiplication occurs in the APD 201, an avalanche multiplication current flows to the quench element 202, and the voltage at the node A drops. When the amount of voltage drop further increases and the potential difference applied to the APD 201 decreases, avalanche multiplication in the APD 201 stops at time t2, and the voltage level at the node A stops dropping from a certain fixed value. Thereafter, during the period from time t2 to time t3, a current that compensates for the amount of voltage drop flows through the node A from the voltage VL. At time t3, the potential level at the node A becomes statically determinate at its original potential level. At this time, the portion of the output waveform in the node A that has exceeded a certain threshold is subjected to waveform shaping by the waveform shaping unit 210, and is output as a signal at the node B.

The layout of the signal lines 113 and the layout of the readout circuit 112 and the output circuit 114 are not limited to those illustrated in FIG. 3. For example, the signal lines 113 can be arranged extending in a row direction, and the readout circuit 112 can be arranged at the end portions of the extending signal lines 113.

A photoelectric conversion apparatus according to each exemplary embodiment will be described below.

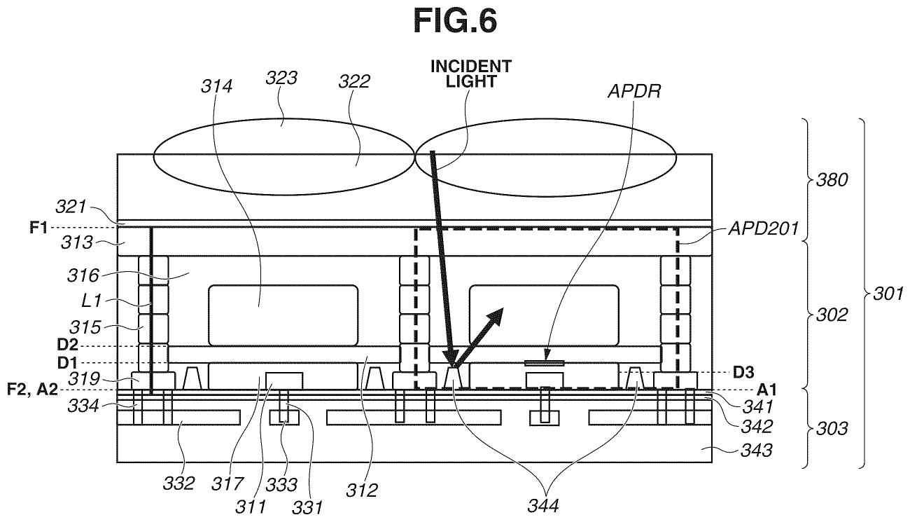

FIG. 6 is a sectional view illustrating the structure of each APD 201 according to the first exemplary embodiment. This sectional view illustrates the APDs 201 corresponding to two pixels 101. The two APDs 201 have the same structure. For convenience of illustration, reference numerals are given to the components of only one of the two APDs 201, but the components are included in both of the APDs 201.

A semiconductor substrate 301 includes a first surface F1 serving as a light incidence surface, and a second surface F2 corresponding to the first surface F1. Above the second surface F2 (direction opposite to the light incidence surface), a wiring layer 303 is provided. The sensor substrate 11 illustrated in FIG. 1 has a configuration of the semiconductor substrate 301 including a semiconductor layer 302 and the wiring layer 303.

The semiconductor substrate 301 is an n-type semiconductor layer that entirely includes donors.

The APD 201 includes an n-type semiconductor region 311 (third semiconductor region), a p-type semiconductor region 312 (second semiconductor region), a p-type semiconductor region 313, an n-type semiconductor region 314 (first semiconductor region), an n-type semiconductor region 316 (fourth semiconductor region), and an n-type semiconductor region 317. The semiconductor region 316 can have a donor concentration corresponding to the original donor concentration of the semiconductor layer 302. The impurity concentration of the donor can also be increased by further performing ion implantation. The impurity concentrations of the semiconductor regions 311, 314, 316, and 317, which are n-type semiconductor regions, have a relationship of 311>317>314>316. The semiconductor region 311 includes a cathode contact 331.

The cathode contact 331 is supplied with a first voltage (positive voltage) via a contact plug from a wire 333.

The APD 201 includes a region having a pixel isolation function and a second voltage application function. This region is referred to as a p-type semiconductor region in the present exemplary embodiment. A semiconductor region 315 and a semiconductor region 319 that are provided at multiple depths are p-type semiconductor regions. Among the semiconductor regions 312, 313, 315 and 319, which are p-type semiconductor regions, the semiconductor region 319 has a highest impurity concentration. The semiconductor region 319 is a region that is in contact with an anode contact 334. The anode contact 334 is supplied with a second voltage (negative voltage) from a wire 332 via a contact plug. For example, the second voltage is approximately −30 V.

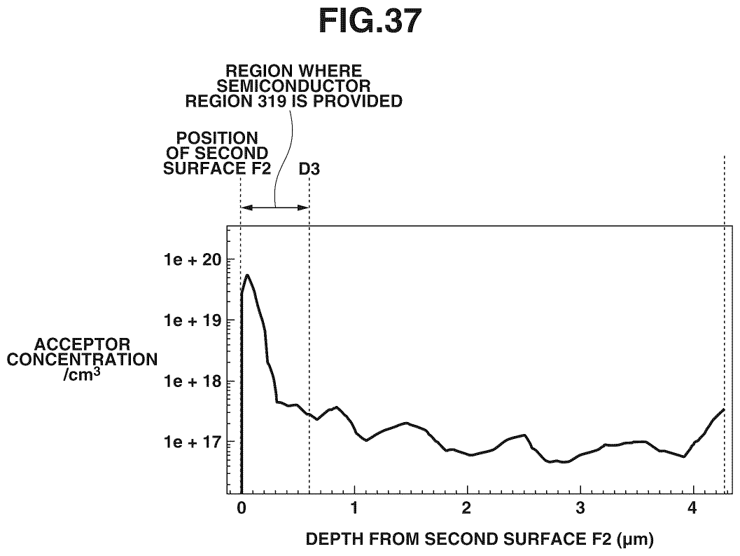

FIG. 37 illustrates a relationship between an impurity concentration (effective impurity concentration) of acceptors at a position indicated by a line L1 illustrated in FIG. 6 and a depth from the second surface F2. The semiconductor region 319 has a peak concentration of about 6×10\hat{ }19 (\hat{ }denotes a power in the present specification)/cm³. The impurity concentration at a position of a depth D3 is about 4×10\hat{ }17/cm³. Thus, in the region at the depth position D3 corresponding to an end portion on the side of the first surface F1 of the semiconductor region 319, the impurity concentration is almost two powers of 10 smaller than the peak concentration. The relationship of the concentration difference is not essential. The concentration at the depth position D3 is typically 1/1000 to 1/50 with respect to the peak concentration. In the present exemplary embodiment, the depth position D3 is about 0.6 μm (micrometers) from the second surface F2. The depth position is not limited to this position. The depth position D3 is typically within a range of 0.4 to 1.5 μm from the second surface F2. While the present exemplary embodiment illustrates an example where a plurality of p-type semiconductor regions 315 is provided at four depth positions, respectively, the configuration of the p-type semiconductor region 315 is not limited to this example.

More p-type semiconductor regions 315 can be provided, or less p-type semiconductor regions 315 can also be provided.

The semiconductor region 312 is supplied with the second voltage from the semiconductor region 315. Accordingly, a voltage exceeding an avalanche breakdown voltage is applied to a PN junction generated between the semiconductor region 317 and the semiconductor region 312. A region that is a part of the semiconductor region 317 and is located between the semiconductor region 311 and the semiconductor region 312 is an n-type semiconductor region (fifth semiconductor region). This causes avalanche multiplication. This PN junction functions as an avalanche multiplication region APDR. This avalanche multiplication is caused when electrons (seed electrons) generated in the semiconductor region 316 or the semiconductor region 314 pass through the avalanche multiplication region APDR. Thus, the electrons that outnumber the seed electrons generated in the semiconductor region 316 or the semiconductor region 314 are delivered to the semiconductor region 311.

The APD 201 further includes the p-type semiconductor region 313. The semiconductor region 313 has a function of reducing dark current components to flow into the semiconductor region 316. The dark current components are generated mainly due to a defect on the surface of the semiconductor layer F1.

On the incidence surface side of the first surface F1, a pinning film (fixed electric charge film) 321 is provided. The pinning film 321 is a film having negative fixed electric charges. The pinning film 321 generates positive electric charges in a region near the first surface F1 in the semiconductor layer 302. The pinning film 321 and the p-type semiconductor region 313 have a function of reducing dark current components to flow into the semiconductor region 317. The dark current components are generated mainly due to a defect on the surface of the semiconductor layer F1. The pinning film 321 is typically an aluminum oxide film, but instead can be a film containing at least one of an aluminum oxide and a tantalum oxide. In the case of using a stacked film of an aluminum oxide film and a tantalum oxide film, the aluminum oxide film and the tantalum oxide film can be stacked in this order from a side closer to the first surface F1.

A planarization film 322 is formed on the pinning film 321. The planarization film 322 can be a film including at least one of a silicon oxide film, a silicon nitride film, and a silicon oxynitride film, or can be a stacked film including a plurality of films. On the planarization film 322, microlenses 323 are provided. Each microlens 323 collects light and causes the light to enter the APD 201. An optical layer 380 includes the pinning film 321, the planarization film 322, and the microlens 323. Between the microlenses 323 and the planarization film 322, a color filter can further be provided. When a plurality of color filters of different colors is provided in a plurality of pixels, respectively, color information can be acquired. Between the pinning film 321 and the planarization film 322, a film having another function can also be provided. For example, the sensitivity of the APD 201 can further be increased by providing an antireflection film.

The semiconductor layer 302 includes a dielectric material 344. The dielectric material 344 can be formed by a LOcal Oxidation Silicon (LOCOS) process, a Shallow Trench Isolation (STI) process, or the like.

The present exemplary embodiment illustrates a structure formed by the STI process. Typically, the dielectric material 344 mainly contains a silicon oxide. In either case of the LOCOS process or the STI process, the dielectric material 344 includes a portion extending to the inside of the semiconductor layer 302. In the case of forming the dielectric material 344 by the LOCOS process or the STI process, the dielectric material 344 can contain a silicon compound. This silicon compound typically includes a silicon oxide film or a silicon oxynitride film. The dielectric material 344 can also include a void. This void can contain a gas, or can be vacuum. The dielectric material 344 extends to a position deeper than the depth position D3 at which the semiconductor region 319 is provided as viewed from the second surface F2. In other words, the depth position D3 is a position at which the semiconductor region 316 is provided. Thus, the dielectric material 344 includes a portion provided at the depth position where the semiconductor region 316 is provided. In other words, the depth position D3 is a depth position at which the semiconductor region 317 is provided. The dielectric material 344 thus includes a portion provided at the depth position where the semiconductor region 317 is provided.

The above-described semiconductor regions are summarized as follows. In the present exemplary embodiment, it is assumed that a first conductivity type is n-type and a second conductivity type is p-type. The semiconductor region 314 corresponds to the first semiconductor region of the first conductivity type provided at a first depth from the first surface F1. The semiconductor region 312 corresponds to the second semiconductor region of the second conductivity type located at a position closer to the second surface F2 than the first semiconductor region. The semiconductor region 311 corresponds to the third semiconductor region of the first conductivity type which is located at a position closer to the second surface F2 than the second semiconductor region and to which the first voltage is applied. The semiconductor region 319 corresponds to the region to which the second voltage different from the first voltage is applied. The fourth semiconductor region of the first conductivity type provided between the region and the third semiconductor region is at least one of the semiconductor region 317 and the portion provided at the depth at which the semiconductor region 319 is provided in the semiconductor region 316. The dielectric material 344 corresponds to a dielectric material that is located at a portion overlapping at least the fourth semiconductor region in a planar view with respect to the second surface F2 and includes a portion extending from at least the second surface F2 to the inside of the semiconductor layer 302. The dielectric material 344 extends to a position deeper than the depth position D3 at which the semiconductor region 319 is provided as viewed from the second surface F2. The dielectric material 344 includes a portion provided at the depth position where the semiconductor region 316 is provided. The dielectric material 344 also includes a portion provided at the depth position where the semiconductor region 317 is provided.

From another perspective, an end portion on the side of the first surface F1 of the dielectric material 344 is located at a position deeper than the depth position D3 at which the semiconductor region 319 is located as viewed from the second surface F2. A part of the dielectric material 344 is provided at the depth position where the semiconductor region 316 is located. A part of the dielectric material 344 is provided at the depth position where the semiconductor region 317 is located.

Referring again to FIG. 6, avalanche multiplication is limited to the avalanche multiplication region APDR, thereby achieving generation of stable avalanche multiplication while suppressing noise in the configuration illustrated in FIG. 6. However, when the area of the APD 201 is reduced in a planar view with respect to the second surface F2 so as to improve the resolution of the photoelectric conversion apparatus, the distance between the semiconductor region 311 having a highest impurity concentration among the n-type semiconductor regions and the semiconductor region 319 having a highest impurity concentration among the p-type semiconductor regions is decreased, so that a tunnel current or avalanche multiplication is generated between the semiconductor region 311 and the semiconductor region 319, which leads to an increase in noise. In the present exemplary embodiment, the PN junction generated between the semiconductor region 311 and the semiconductor region 319 can be isolated by providing the dielectric material 344, thereby making it possible to suppress generation of the tunnel current or avalanche multiplication. As a result, the avalanche multiplication can be limited to the avalanche multiplication region APDR, thereby making it possible to improve the resolution of the photoelectric conversion apparatus and generate stable avalanche multiplication while suppressing noise. The dielectric material 344 also extends to a position deeper than the depth position D3 at which the semiconductor region 319 is located as viewed from the second surface F2. With this configuration, a leakage current between the anode region and the cathode region can be reduced even when the distance between the semiconductor region 319 corresponding to the anode region and the semiconductor region 311 corresponding to the cathode region is decreased due to miniaturization of the pixel structure.

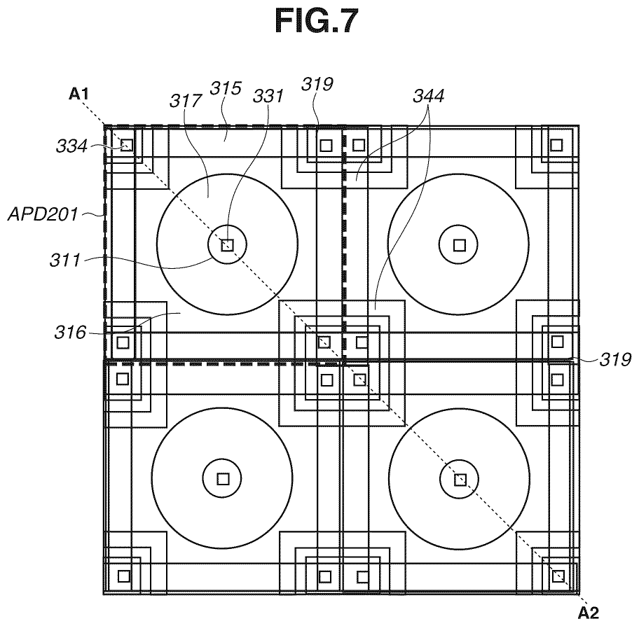

FIG. 7 is a plan view of the structure illustrated in FIG. 6 as viewed from the second surface F2. Members illustrated in FIG. 7 that are similar to those illustrated in FIG. 6 are denoted by the same reference numerals as those in FIG. 6. FIG. 7 illustrates a configuration example of the APD 201 including four pixels arranged in two rows and two columns. FIG. 6 is a sectional view taken along the line A1-A2 illustrated in FIG. 7.

As illustrated in FIG. 7, the dielectric material 344 is provided in a square ring shape to surround the semiconductor region 319. This shape makes it possible to isolate the PN junction generated between the semiconductor region 311 and the semiconductor region 319. The semiconductor region 312 is provided at a position overlapping the semiconductor region 316 illustrated in FIG. 7. The portion in which the semiconductor region 316 is provided and the portion in which the semiconductor region 312 is provided typically match in a plan view from the second surface F2.

Next, a manufacturing method of the photoelectric conversion apparatus described above with reference to FIGS. 6 and 7 according to the present exemplary embodiment will be described.

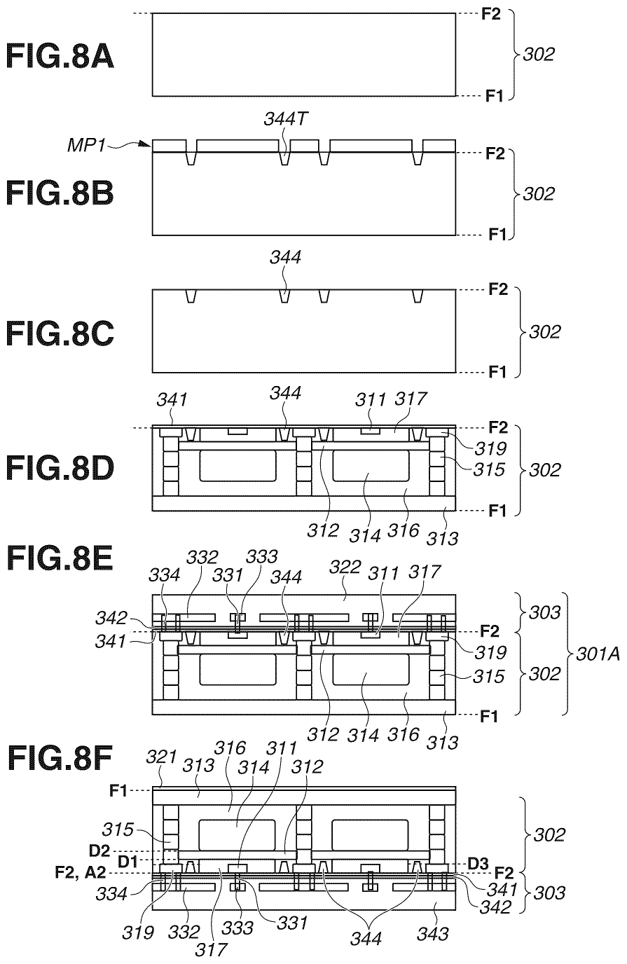

FIGS. 8A to 8F illustrate some of processes for the manufacturing method of the photoelectric conversion apparatus according to the present exemplary embodiment.

As illustrated in FIG. 8A, a silicon wafer including the n-type semiconductor layer 302 into which donors are entirely introduced is prepared.

As illustrated in FIG. 8B, a mask pattern MP1 is formed by photolithography, and then a trench portion 344T is formed by reactive icon etching such as dry etching. The trench portion 344T is formed at a location where the dielectric material 344 is to be provided.

As illustrated in FIG. 8C, the mask pattern MP1 is removed, and then a silicon oxide (SiO₂) film is deposited in the trench portion 344T by chemical vapor deposition (CVD). The excess silicon oxide is then removed by chemical mechanical polishing (CMP) and the dielectric material 344 is formed. In this case, the dielectric material 344 is formed before the formation of the other semiconductor regions 311 to 315, 317, and 319. A sufficient annealing treatment can therefore be carried out after the formation of the dielectric material 344. In a case where the dielectric material 344 is formed after the formation of the semiconductor regions 311 to 315, 317, and 319, impurities in the semiconductor regions are diffused when an annealing treatment is performed, which makes it difficult to create a device with an appropriate concentration distribution. Accordingly, it is difficult to carry out a sufficient annealing treatment. In the present exemplary embodiment, a sufficient annealing treatment can be carried out by forming the dielectric material 344 before the formation of the semiconductor regions. This can thereby reduce a dark current that is more likely to be generated due to a defect in the semiconductor layer 302 in the process of forming the dielectric material 344.

As illustrated in FIG. 8D, the semiconductor regions 311 to 315, 317, and 319 are formed by ion implantation. In this case, it may be preferable to form a silicon oxide film 341 first and then perform ion implantation on the semiconductor regions 311 to 315, 317, and 319. This method can reduce damage to the semiconductor layer 302 due to ion implantation.

As illustrated in FIG. 8E, a silicon nitride film 342 is formed, and then the wiring layer 303 including the wire 333, the anode contact 334, the cathode contact 331, the wire 332, and the planarization film 322 is formed. This process enables formation of a semiconductor substrate 301A obtained before a stacked sensor (structure).

After this process, the semiconductor substrate 301A (one substrate) is bonded to the circuit substrate 21 (another substrate) illustrated in FIG. 1, thereby forming the stacked sensor. Various bonding methods can be employed for this bonding process. For example, a silicon oxide film is formed on a bonding surface between the semiconductor substrate 301A and the circuit substrate 21. A dent is formed in a part of the silicon oxide film of each of the semiconductor substrate 301A and the circuit substrate 21, and a conductive member is embedded into the dent. This conductive member is electrically connected to the wiring layer located in the lower layer via a via-plug. A metal material such as copper, aluminum, or tungsten may be used for this conductive member. The conductive members of the semiconductor substrate 301A and the circuit substrate 21 are bonded together. The silicon oxide films of the semiconductor substrate 301A and the circuit substrate 21 are bonded together on the bonding surface. In other words, the silicon oxide films bonded together and the conductive members bonded together are formed on the bonding surface. This is also referred to as hybrid bonding. This bonding method enables bonding and electric connection between the semiconductor substrate 301A and the circuit substrate 21.

FIG. 8F illustrates a process for the semiconductor substrate 301A after bonding. In FIG. 8F, the first surface F1 is illustrated on the upper side and the second surface F2 is illustrated on the lower side, unlike in FIG. 8E. Before the process illustrated in FIG. 8F, a process of reducing the thickness of the semiconductor layer 302 is included. The semiconductor layer 302 is typically adjusted to a thickness of 1 to 10 μm. To improve the sensitivity of light with a long wavelength such as infrared light, the semiconductor layer 302 can have a greater thickness (e.g., a thickness of 10 to 100 μm). As illustrated in FIG. 8F, the pinning film 321 is formed by atomic layer deposition (ALD) on the first surface F1, which is a surface on the incidence surface side of the semiconductor substrate 301A after bonding. Thereafter, the planarization film 322 and the microlens 323 are formed to thereby manufacture the photoelectric conversion apparatus having the structure illustrated in FIG. 6.

In the present exemplary embodiment, the dielectric material 344 extends, as described above, to a position deeper than the depth position D3 at which the semiconductor region 319 is provided as viewed from the second surface F2. The dielectric material 344 includes the portion provided at the depth position where the semiconductor region 316 is provided. The dielectric material 344 also includes the portion provided at the depth position where the semiconductor region 317 is located. This configuration can reduce a leakage current between the semiconductor region 319 corresponding to the anode region and the semiconductor region 311 corresponding to the cathode region even when the semiconductor region 319 corresponding to the anode region and the semiconductor region 311 corresponding to the cathode region are located close to each other due to miniaturization of the pixel structure.

The provision of the dielectric material 344 makes it possible to guide incident light to the semiconductor region 314 by reflecting the incident light on the dielectric material 344. The sensitivity of the APD 201 can thereby be improved.

Differences between the first exemplary embodiment and a second exemplary embodiment will mainly be described. The second exemplary embodiment is a modified example of the layout of the dielectric materials 344.

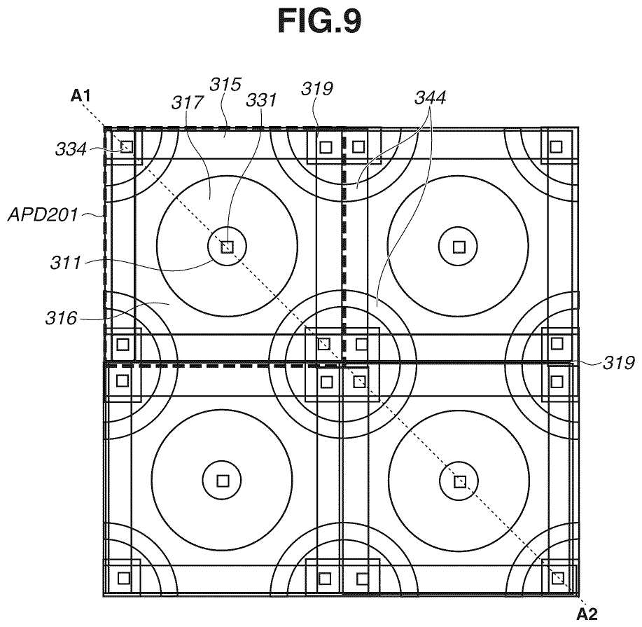

FIG. 9 is a plan view illustrating a layout of the dielectric materials 344 serving as a modified example as viewed from the second surface F2. This layout indicates a configuration in which each dielectric material 344 is formed in a circular ring shape. This circular ring shape is not limited to a precise circle. That is, an elliptical shape can also be used.

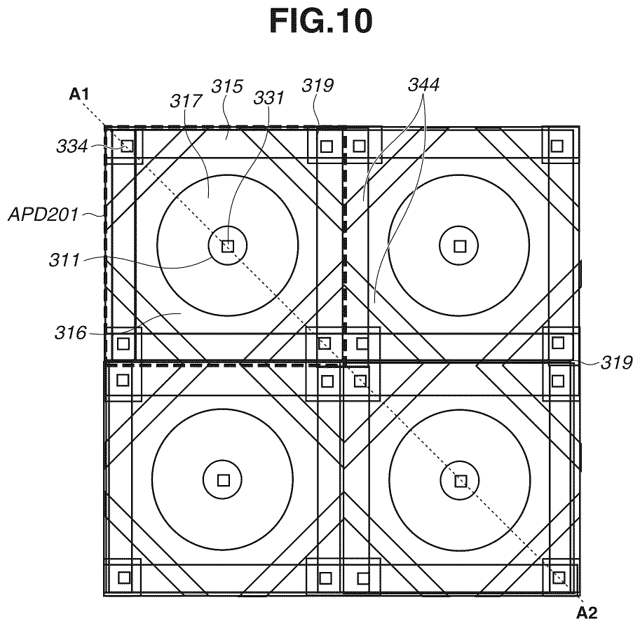

FIG. 10 is a plan view illustrating a layout of the dielectric materials 344 serving as a modified example as viewed from the second surface F2. This layout indicates a configuration in which each dielectric material 344 is formed in a quadrilateral shape. This quadrilateral shape is a quadrangle having four corners. Each angle of the quadrilateral shape is not limited to 90 degrees. That is, the quadrilateral shape can include a parallelogram and a rhomboid. The shape illustrated in FIG. 10 is a rhomboid.

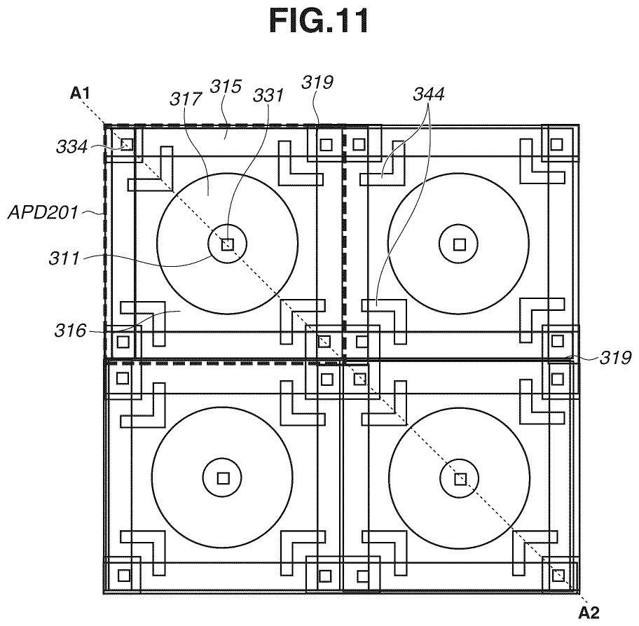

FIG. 11 is a plan view illustrating a layout of the dielectric material 344, which is a modified example, as viewed from the second surface F2. In this configuration, each side portion of a quadrilateral is divided. The dielectric materials 344 are not continuously formed across a plurality of APDs 201, and each dielectric material 344 is provided in a single APD 201. In this configuration, the PN junction generated between the semiconductor region 311 and the semiconductor region 319 can also be isolated.

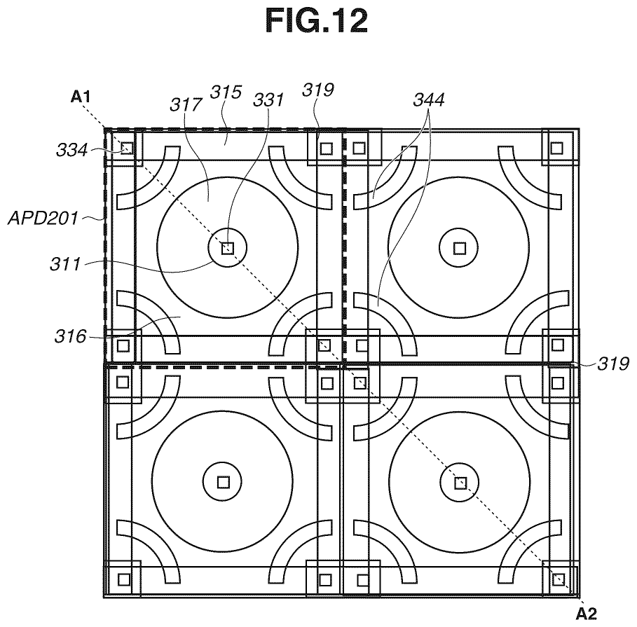

FIG. 12 is a plan view illustrating a layout of the dielectric materials 344, which is a modified example, as viewed from the second surface F2. In this configuration, a circular ring is divided. The dielectric materials 344 are not continuously formed across a plurality of APDs 201, and each dielectric material 344 is provided in a single APD 201.

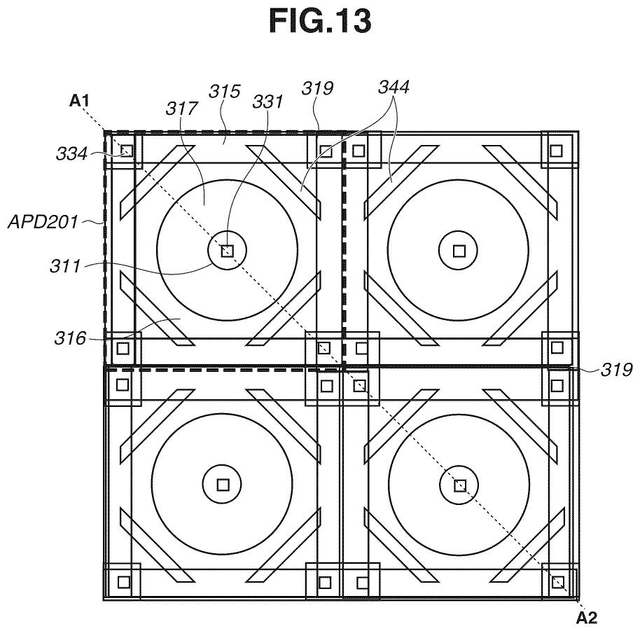

FIG. 13 is a plan view illustrating a layout of the dielectric materials 344, which is a modified example, as viewed from the second surface F2. In this configuration, a rhombic ring is divided, the dielectric materials 344 are not continuously formed across a plurality of APDs 201, and each dielectric material 344 is provided in a single APD 201.

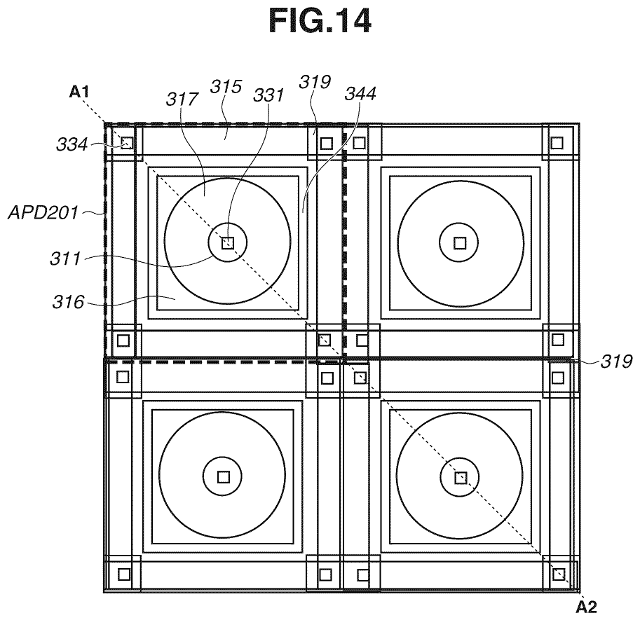

FIG. 14 is a plan view illustrating a layout of the dielectric materials 344, which is a modified example, as viewed from the second surface F2. In this configuration, each dielectric material 344 having a quadrilateral ring shape is provided on the outer periphery of the quadrilateral about the cathode contact 331.

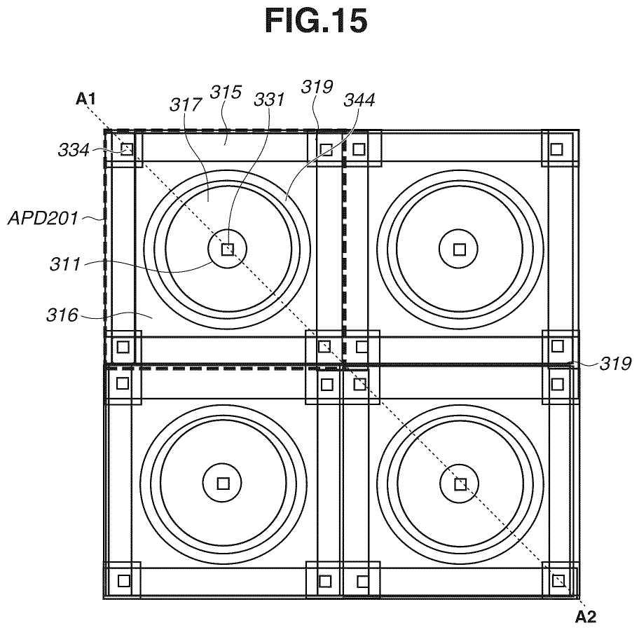

FIG. 15 is a plan view illustrating a layout of the dielectric materials 344, which is a modified example, as viewed from the second surface F2. In this configuration, each dielectric material 344 having a circular ring shape is provided on the circumference of the circle about the cathode contact 331.

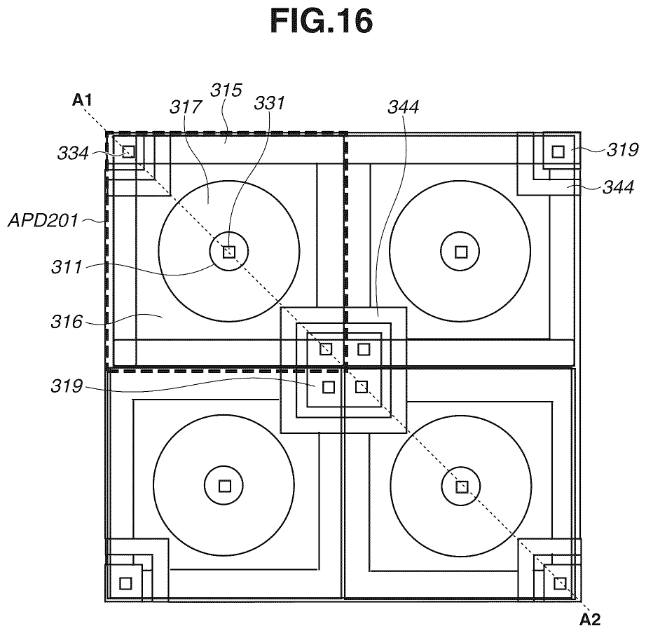

FIG. 16 is a plan view illustrating a layout of the dielectric material 344, which is a modified example, as viewed from the second surface F2. In this configuration, the semiconductor region 319 and the anode contact 334 are provided only at some of the four corners of a single APD 201, and each dielectric material 344 surrounds the semiconductor region 319. In the configurations illustrated in FIGS. 9 to 13, the semiconductor region 319 and the anode contact 334 can also be provided only at some of the four corners of a single APD 201 as illustrated in FIG. 16.

Advantageous effects described in the first exemplary embodiment can also be obtained in the examples of the present exemplary embodiment.

Specifically, a leakage current between the semiconductor region 319 corresponding to the anode region and the semiconductor region 311 corresponding to the cathode region can be reduced. Similarly to the first exemplary embodiment, the provision of the dielectric material 344 makes it possible to guide incident light to the semiconductor region 314 by reflecting the incident light on the dielectric material 344. The sensitivity of the APD 201 can thereby be improved.

Differences between the first exemplary embodiment and a third exemplary embodiment will be mainly described.

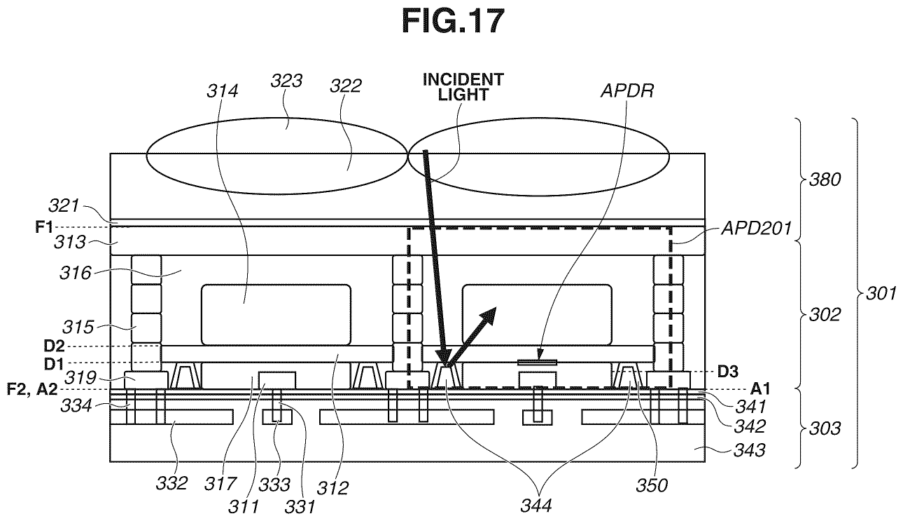

FIG. 17 is a sectional view illustrating a photoelectric conversion apparatus according to the third exemplary embodiment. In the third exemplary embodiment, a p-type semiconductor region 350 is formed at a boundary surface between the dielectric material 344 and the n-type semiconductor layer 302.

The impurity concentrations of the p-type semiconductor regions 312, 319, and 350 have a relationship of 319>312>350. The dielectric material 344 and the semiconductor layer 302 are made of different materials, respectively, so that dangling bonds occur at the boundary surface and a dark current is generated due to the capture and emission of the electrons of the dangling bonds. However, when the p-type semiconductor region 350 is formed, holes in the semiconductor region 350 can cancel out the dark current.

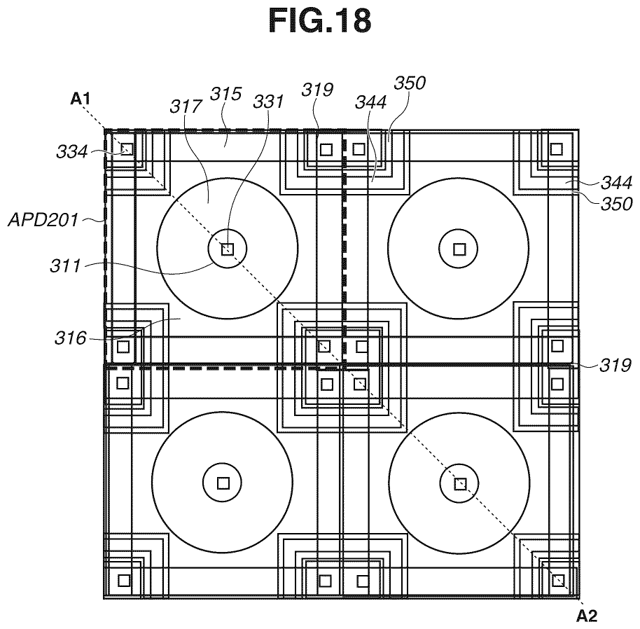

FIG. 18 is a plan view as viewed from the second surface F2 according to the third exemplary embodiment. FIG. 17 is a sectional view taken along the line A1-A2 illustrated in FIG. 18. As viewed from the semiconductor region 319, the semiconductor region 350 is formed at the outer periphery and the inner periphery of the dielectric material 344. This structure makes it possible to cancel out the dark current generated at the boundary surface between the dielectric material 344 and the semiconductor layer 302.

Next, a manufacturing method of the photoelectric conversion apparatus described above with reference to FIGS. 17 and 18 from among the present exemplary embodiments will be described.

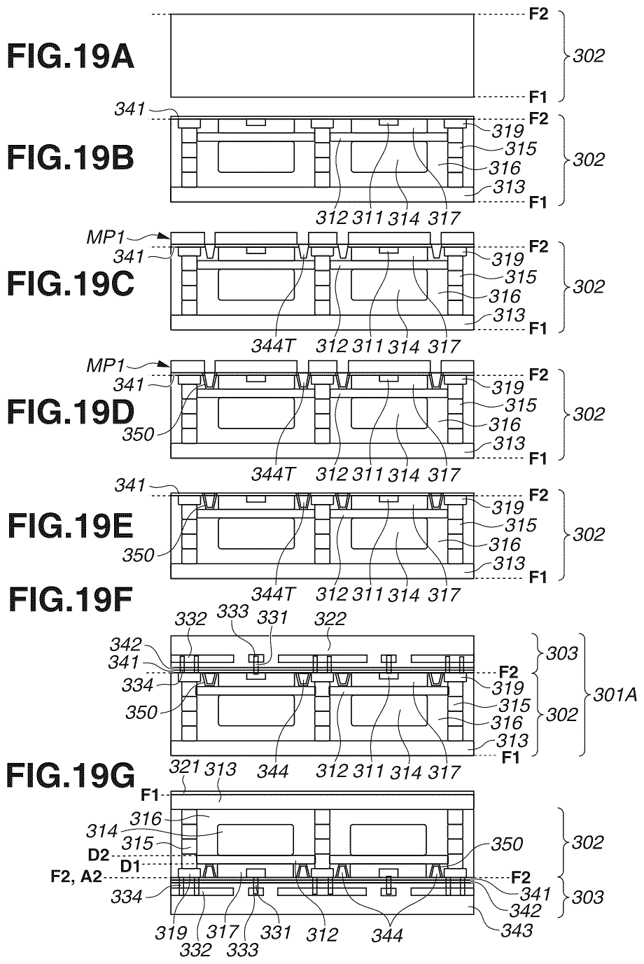

FIGS. 19A to 19G illustrate some of processes for the manufacturing method of the photoelectric conversion apparatus according to the third exemplary embodiment.

As illustrated in FIG. 19A, a silicon wafer including the n-type semiconductor layer 302 (epitaxial layer) in which donors are entirely introduced is prepared.

As illustrated in FIG. 19B, the semiconductor regions 311 to 315, 317, and 319 are formed by ion implantation. In this case, it may be preferable to form the silicon oxide film 341 first and then perform ion implantation on the semiconductor regions 311 to 315, 317, and 319. This method makes it possible to reduce damage to the semiconductor layer 302 due to ion implantation.

As illustrated in FIG. 19C, the mask pattern MP1 is formed by photolithography, and then the trench portion 344T is formed by reactive icon etching such as dry etching. The trench portion 344T is formed at a location where the dielectric material 344 is to be provided.

As illustrated in FIG. 19D, the semiconductor region 350 is formed by plasma doping on the inner surface of the trench portion 344T. This method makes it possible to reduce damage to the trench portion 344T.

As illustrated in FIG. 19E, the mask pattern MP1 is removed and then a silicon oxide (SiO₂) film is deposited in the trench portion 344T by CVD. The excess silicon oxide is then removed by CMP, and the dielectric material 344 is formed. In this case, the other semiconductor regions 311 to 315, 317, and 319 are formed and then the dielectric material 344 is formed. It is therefore difficult to carry out a sufficient annealing treatment after the formation of the dielectric material 344. However, a dark current can be reduced by the semiconductor region 350.

The photoelectric conversion apparatus having the structure illustrated in FIG. 17 can be manufactured through processes similar to those of the first exemplary embodiment as illustrated in FIGS. 19F and 19G.

A fourth exemplary embodiment will now be described centering on differences from the third exemplary embodiment.

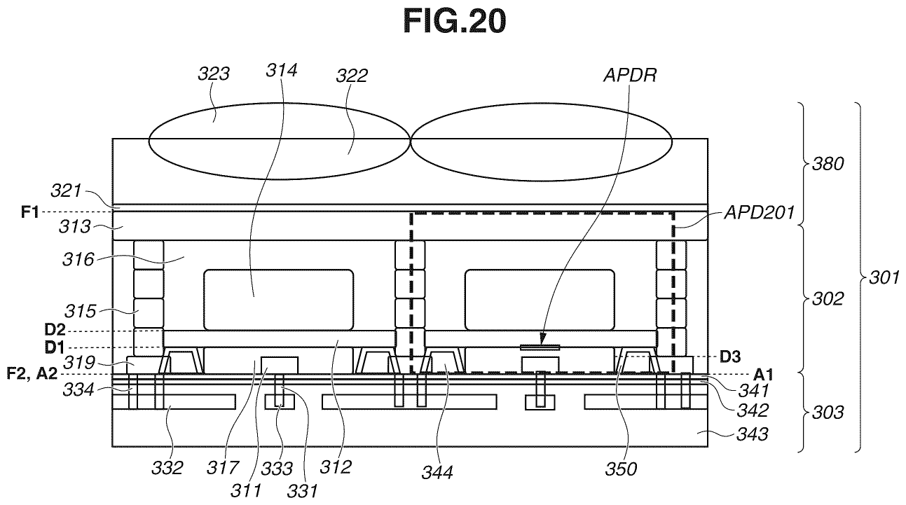

FIG. 20 is a sectional view of a photoelectric conversion apparatus according to the fourth exemplary embodiment. In the fourth exemplary embodiment, the dielectric material 344 is provided in contact with the semiconductor region 319. The impurity concentrations of the semiconductor regions 319 and 350, which are p-type semiconductor regions, have a relationship of 319>350, so that the effect of reducing a dark current can be increased.

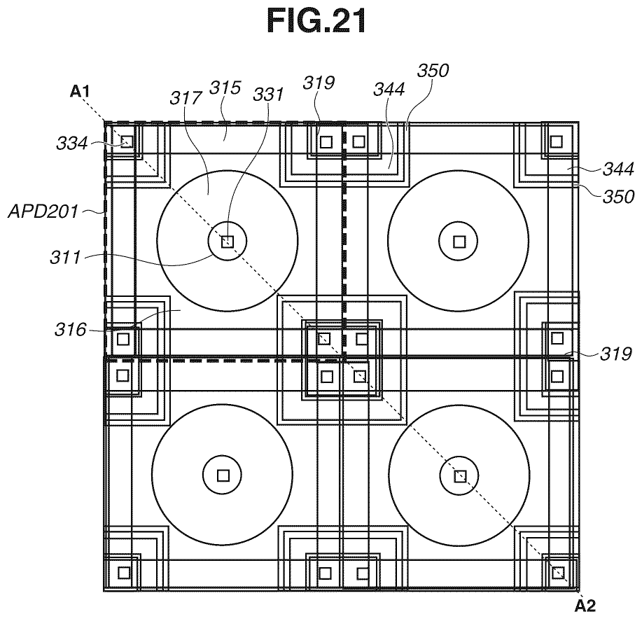

FIG. 21 is a plan view as viewed from the second surface F2 according to the fourth exemplary embodiment. FIG. 20 is a sectional view taken along the line A1-A2 illustrated in FIG. 21. As viewed from the semiconductor region 319, the semiconductor region 350 is formed at the outer periphery of the dielectric material 344 and the inner periphery of the dielectric material 344 is in contact with the semiconductor region 319. The dielectric material 344 according to the fourth exemplary embodiment has a quadrilateral ring shape, but instead can have any other shape such as a modified example of the second exemplary embodiment.

A fifth exemplary embodiment will now be described on a modified example having the dielectric material 344 according to the first exemplary embodiment located at a different depth from the second surface F2. A layout of the dielectric material 344 in a planar view with respect to the first surface F1 can be similar to that in the configurations described in the first to fourth exemplary embodiments.

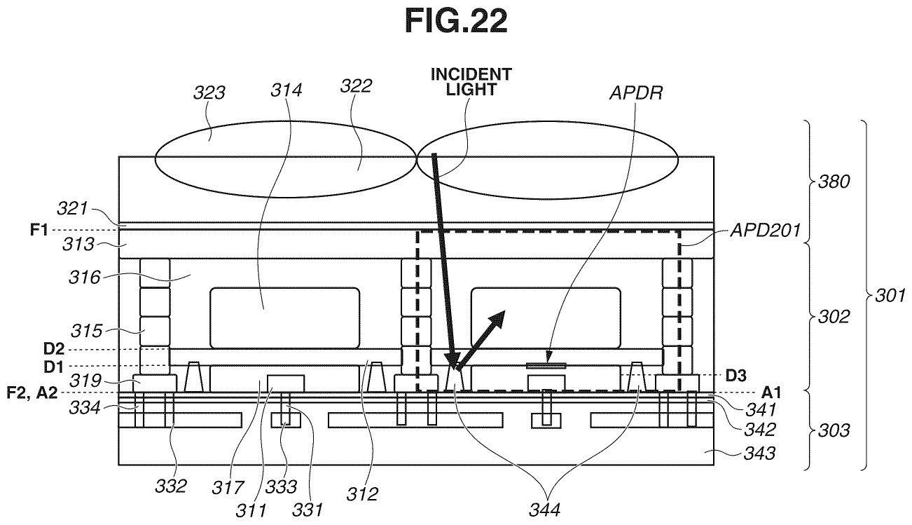

FIG. 22 is a sectional view illustrating a depth of the dielectric material 344 from the second surface F2 as one modified example. An end portion on the side of the first surface F1 of the dielectric material 344 extends to the depth position at which the semiconductor region 312 is provided as viewed from the second surface F2. The semiconductor region 312 is located extending to a fifth depth position D2 from a fourth depth position D1 as viewed from the side of the second surface F2. An end portion on the side of the first surface F1 of the dielectric material 344 is located at a position that is deeper than the fourth depth position D1 and is shallower than the fifth depth position D2 as viewed from the second surface F2. From another perspective, an end portion on the side of the first surface F1 of the dielectric material 344 is located at a position that is shallower than the fourth depth position D1 and is deeper than the fifth depth position D2 as viewed from the first surface F1. This configuration allows the dielectric material 344 to be located at a deeper position in the semiconductor layer 32 as compared with the configuration of the dielectric material 344 described in the first exemplary embodiment. The PN junction generated between the semiconductor region 311 and the semiconductor region 319 can thereby be easily isolated. This configuration can reduce a leakage current between the semiconductor region 319 corresponding to the anode region and the semiconductor region 311 corresponding to the cathode region.

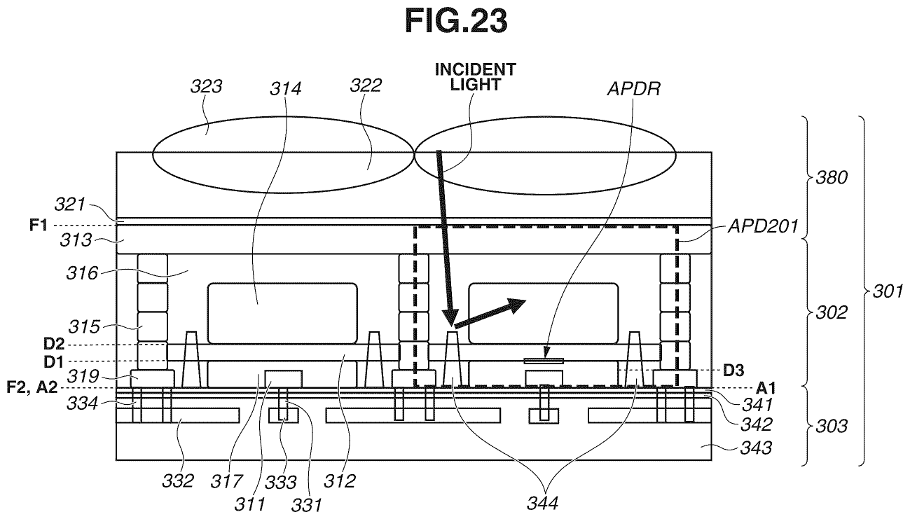

FIG. 23 illustrates another modified example (sixth exemplary embodiment) of the fifth exemplary embodiment. In this configuration, in a planar view with respect to the first surface F1, the dielectric material 344 has a layout in which the configurations illustrated in FIGS. 14 and 15 are excluded from the configurations described in the first to fourth exemplary embodiments. FIG. 23 is a sectional view illustrating a depth of the dielectric material 344 from the second surface F2. The depth of the dielectric material 344 reaches the semiconductor region 316 through the semiconductor region 312. In other words, in this configuration, an end portion on the side of the first surface F1 of the dielectric material 344 extends over the depth position D2 at which the semiconductor region 312 is provided as viewed from the second surface F2. Similarly to the configuration illustrated in FIG. 22 described above, the semiconductor region 312 is located extending to the fifth depth position D2 from the fourth depth position D1 as viewed from the side of the second surface F2. An end portion on the side of the first surface F1 of the dielectric material 344 is located at a position that is deeper than the fourth depth position D1 and the fifth depth position D2 as viewed from the second surface F2 (shallower as viewed from the first surface F1). This configuration allows the dielectric material 344 to be located at a deeper position in the semiconductor layer 302 as compared with the configuration of the dielectric material 344 illustrated in FIG. 22. The PN junction generated between the semiconductor region 311 and the semiconductor region 319 can thereby be easily isolated. This configuration can reduce a leakage current between the semiconductor region 319 corresponding to the anode region and the semiconductor region 311 corresponding to the cathode region.

The dielectric material 344 also penetrates through the semiconductor region 312 at the position of the dielectric material 344 in the sectional view illustrated in FIG. 23. However, in the sixth exemplary embodiment, the second voltage can be supplied to the avalanche multiplication region APDR from the semiconductor region 319 through a portion where the semiconductor region 315 or the dielectric material 344 is divided.

Even in these configurations, the PN junction generated between the semiconductor region 311 and the semiconductor region 319 can be isolated. Thus, the advantageous effects described in the first exemplary embodiment can also be obtained in the examples of the present exemplary embodiment. Specifically, a leakage current between the semiconductor region 319 corresponding to the anode region and the semiconductor region 311 corresponding to the cathode region can be reduced. Similarly to the first exemplary embodiment, the provision of the dielectric material 344 makes it possible to guide incident light to the semiconductor region 314 by reflecting the incident light on the dielectric material 344. The sensitivity of the APD 201 can thereby be improved.

A seventh exemplary embodiment will now be described on a configuration example in which the present disclosure is applied to the configuration discussed in Japanese Patent Application Laid-Open No. 2022-55214. Differences between the first exemplary embodiment and the seventh exemplary embodiment will mainly be described.

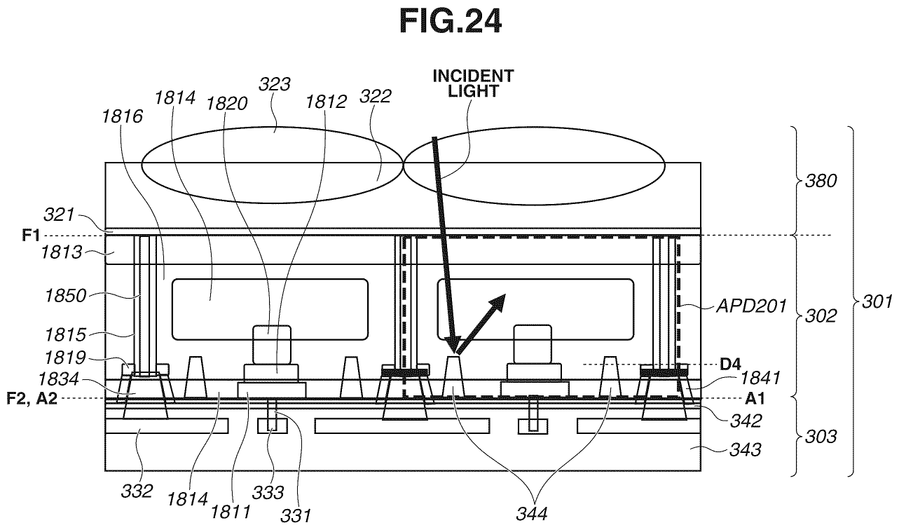

FIG. 24 is a sectional view of a photoelectric conversion apparatus according to the seventh exemplary embodiment. This sectional view is also taken along the line A1-A2 as described above in the first exemplary embodiment.

An n-type semiconductor region 1814 is provided in a p-type semiconductor region 1816. Photoelectric conversion is performed mainly on the n-type semiconductor region 1814. An n-type semiconductor region 1820 has an impurity concentration (effective donor concentration) higher than that of the semiconductor region 1814.

The APD 201 includes a p-type semiconductor region 1812 and an n-type semiconductor region 1811. The cathode contact 331 is connected to the n-type semiconductor region 1811. In the anode portion, an anode electrode 1834 (metallic member) is embedded into a groove formed in the semiconductor layer 302. A silicon oxide film 1841 is formed to surround the outer periphery of the anode electrode 1834. The anode electrode 1834 is in contact with a p-type semiconductor region 1819. To block light between the plurality of APDs 201, a light-shielding portion 1850 is provided from the side of the first surface F1. An insulating film 1815 is provided to surround the light-shielding portion 1850. The insulating film 1815 can include the pinning film 321.

Electric charges generated by photoelectric conversion move to the semiconductor region 1820 from the semiconductor region 1814 and reach the semiconductor region 1812. A voltage applied to the p-type semiconductor region 1819 is supplied to the semiconductor region 1812 through the p-type semiconductor region 1816. Thus, avalanche multiplication occurs at the PN junction between the semiconductor region 1812 and the semiconductor region 1811.

In the seventh exemplary embodiment, the p-type semiconductor region 1819 corresponds to the region to which the second voltage different from the first voltage applied to the semiconductor region 1811 is applied.

In the seventh exemplary embodiment, the dielectric material 344 is provided between the semiconductor region 1819 and the semiconductor region 1811. The dielectric material 344 extends to a position deeper than a depth of the semiconductor region 1819 from the second surface F2. An end portion on the side of the first surface F1 of the dielectric material 344 is located at a position deeper than a depth position D4 at which the semiconductor region 1819 is located as viewed from the second surface F2. In this configuration, the PN junction generated between the semiconductor region 1819 and the semiconductor region 1811 can be isolated, so that the leakage current can be reduced. Similarly to the first exemplary embodiment, the provision of the dielectric material 344 makes it possible to guide incident light to the semiconductor region 1814 by reflecting the incident light on the dielectric material 344. This configuration can improve the sensitivity of the APD 201.

An eighth exemplary embodiment will now be described on a modified example of the layout of the dielectric materials 344 according to the first exemplary embodiment.

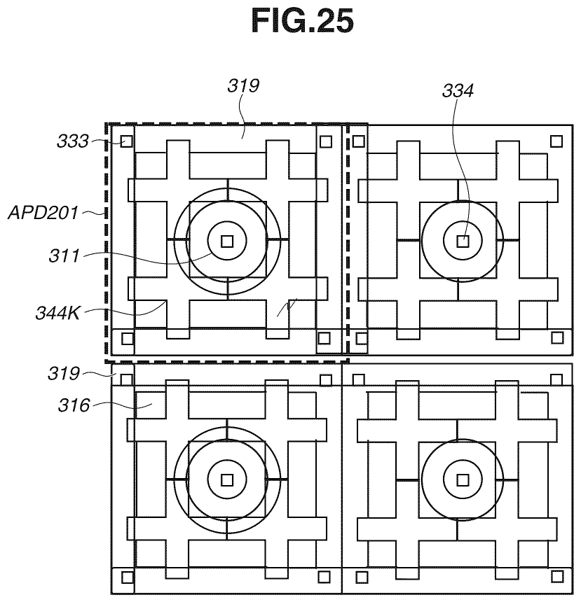

FIG. 25 is a plan view illustrating a layout of dielectric materials 344K serving as a modified example as viewed from the second surface F2. In this layout, the dielectric materials 344K are provided in a lattice shape. FIG. 25 illustrates a configuration example in which the lattice-shaped dielectric materials 344K are provided in a single APD 201. As another configuration example, the lattice-shaped dielectric materials 344K can be continuously formed across the plurality of APDs 201 without being divided between the plurality of APDs 201.

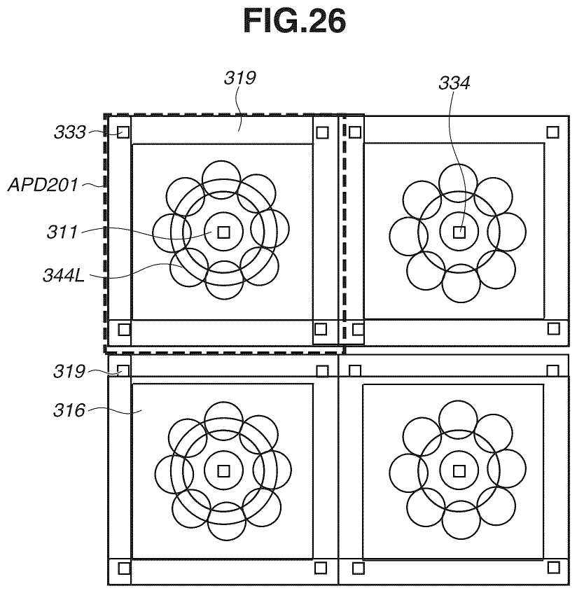

FIG. 26 is a plan view illustrating a layout of dielectric materials 344L as another modified example as viewed from the second surface F2. In this layout, the circular dielectric materials 344L are provided on the circumference of the circle about the cathode contact 331.

In these configurations, it is also possible to suitably guide incident light to the semiconductor region 314 by reflecting the incident light, thereby improving the sensitivity of the APD 201.

A ninth exemplary embodiment will now be described centering on differences from the first exemplary embodiment.

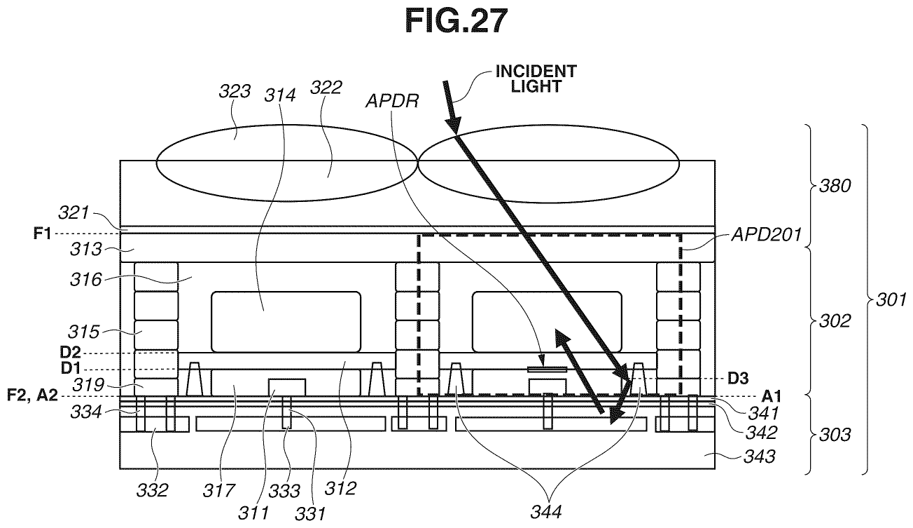

In the ninth exemplary embodiment, as illustrated in FIG. 27, the wire 333 is arranged to overlap the dielectric material 344 in a planar view. With this configuration, light reflected by the dielectric material 344 enters the semiconductor layer 302 via the wire 333.

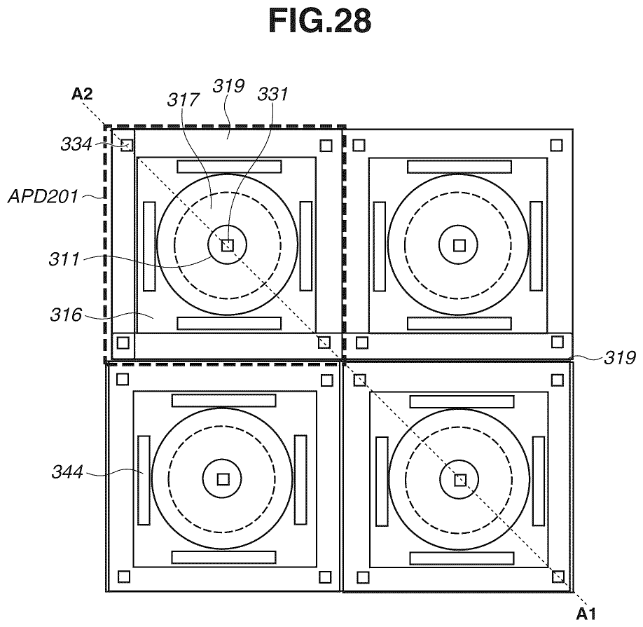

In the ninth exemplary embodiment, the dielectric material 344 can be provided in a rectangular shape to surround the semiconductor region 317, or can have a configuration as illustrated in FIG. 28. The dielectric material 344 is provided between the semiconductor regions 317 of two APDs 201 that are adjacent to each other in the row direction. The dielectric material 344 is also provided between the semiconductor regions 317 of two APDs 201 that are adjacent to each other in a column direction. In contrast, the dielectric materials 344 are not provided at diagonal line positions of each APD 201, and the semiconductor region 316 is provided at the depth position. Even in this configuration, the effect of improving the sensitivity of the APD 201 can be obtained.

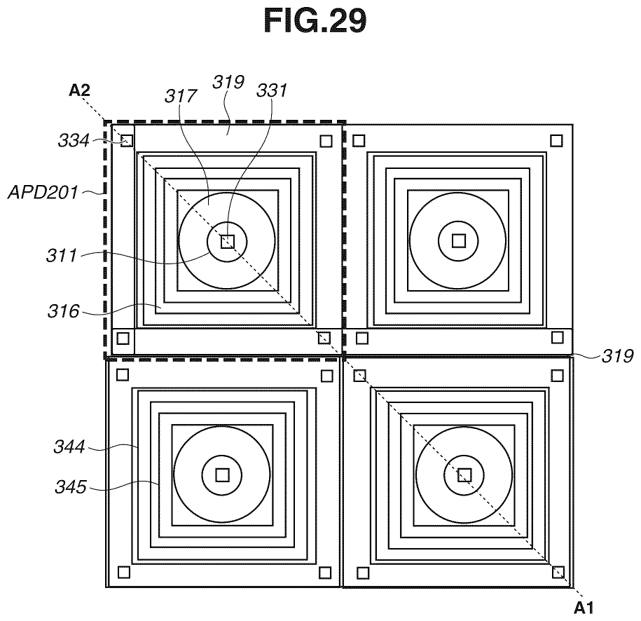

As another configuration, another dielectric material 345 can also be provided on the inside of the rectangular dielectric material 344, as illustrated in FIG. 29. As illustrated in FIG. 28, the dielectric materials 344 and 345 may not be provided at diagonal line positions of each APD 201, and the semiconductor region 316 can be provided at the depth position. The dielectric material 345 can be provided at a position overlapping the semiconductor region 317 in a planar view. In other words, the dielectric material 344 can be located, in a planar view, at a position overlapping the semiconductor region 316 between the semiconductor region 317 and the semiconductor region 319, and the dielectric material 345 can be located at a position overlapping the semiconductor region 317.

The depth position of an end portion on the side of the first surface F1 of the dielectric material 344 and the depth position of an end portion on the side of the first surface F1 of the dielectric material 345 can be determined depending on a combination with other exemplary embodiment. Specifically, the depth position on the side of the first surface F1 of each of the dielectric material 344 and the dielectric material 345 can be a position deeper than the depth position D2 as viewed from the second surface F2. The depth position on the side of the first surface F1 of the dielectric material 344 can be different from the depth position on the side of the first surface F1 of the dielectric material 345. For example, the depth position of the end portion on the side of the first surface F1 of the dielectric material 344 can be a depth position between the depth position D1 and the depth position D3, and the depth position of the end portion on the side of the first surface F1 of the dielectric material 345 can be a depth position between the depth position D2 and the depth position D3. The depth position of the end portion on the side of the first surface F1 of at least one of the dielectric material 344 and the dielectric material 345 can be a position deeper than the depth position D3 as viewed from the second surface F2.

Even in the ninth exemplary embodiment, advantageous effects similar to those of the first exemplary embodiment can be obtained. The configuration in which the wire 333 extends to a position overlapping the dielectric material 344 in a planar view makes it possible to improve the sensitivity of the APD 201.

A tenth exemplary embodiment will now be described centering on differences between the ninth exemplary embodiment.

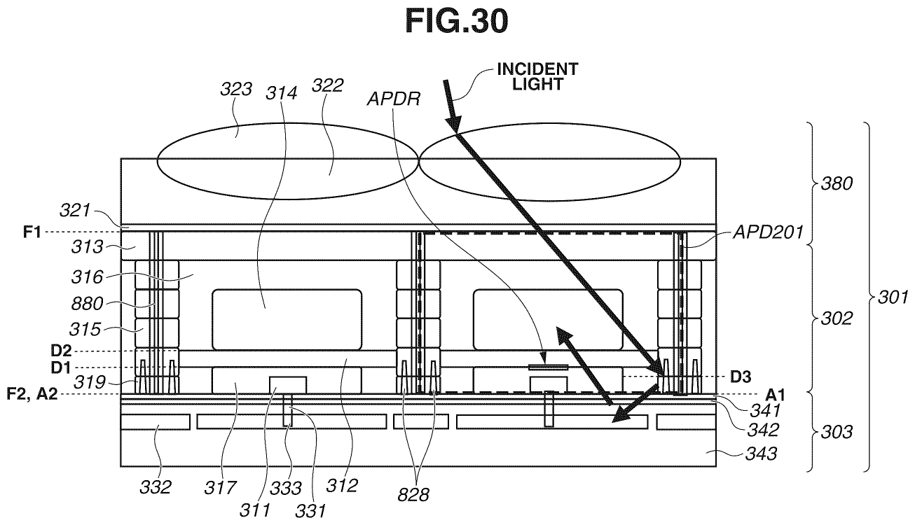

FIG. 30 is a sectional view of an APD according to the ninth exemplary embodiment. The APD according to the ninth exemplary embodiment includes a trench portion 880 extending from the first surface F1 to the second surface F2. The trench portion 880 includes a deep trench isolation (DTI) structure. In the trench portion 880, a silicon compound can be filled or contained, or the trench portion 880 can include a void. This void can contain air, or can be vacuum. Metal can be embedded into the trench portion 880. In a case where metal is embedded into the trench portion 880, the light-shielding performance of the trench portion 880 can be enhanced, so that crosstalk from one APD to another APD can be reduced. This crosstalk is caused by an avalanche light emission caused in one APD entering another APD. The trench portion 880 can prevent the avalanche light emission from entering another APD. The trench portion 880 is provided in the semiconductor region 315 corresponding to a sixth semiconductor region. The semiconductor region 315 is a semiconductor region provided between a plurality of APDs. A trench portion 828 (a modified example of the dielectric material 344) is provided in the semiconductor region 319. In the tenth exemplary embodiment, the trench portion 828 also includes a portion provided in the semiconductor region 315. An end portion on the side of the first surface F1 of the trench portion 828 is located at a depth position between the depth position D1 and the depth position D2 as viewed from the second surface F2. The configuration of the trench portion 828 is not limited to this example. The end portion on the side of the first surface F1 of the trench portion 828 can include a portion extending to a position deeper than at least the depth position D3 as viewed from the second surface F2, or can be located at a depth position deeper than the depth position D2.

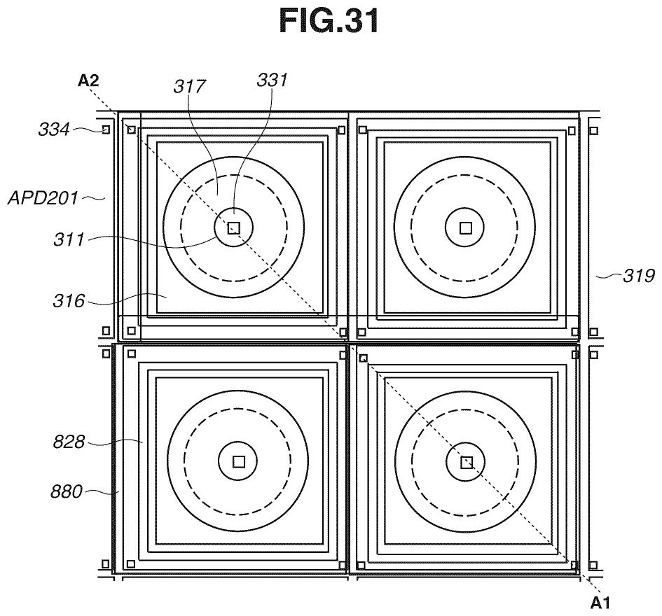

FIG. 31 is a plan view of the APD illustrated in FIG. 30 as viewed from the second surface F2. FIG. 30 is a sectional view taken along the line A1-A2 illustrated in FIG. 31. The trench portion 828 is provided to surround the semiconductor region 316 in a planar view. The trench portion 880 is provided to surround the trench portion 828. With this configuration, the sensitivity of the APD can be improved by the reflection of incident light on the trench portion 880 and the trench portion 828. Crosstalk between the plurality of APDs can also be reduced.

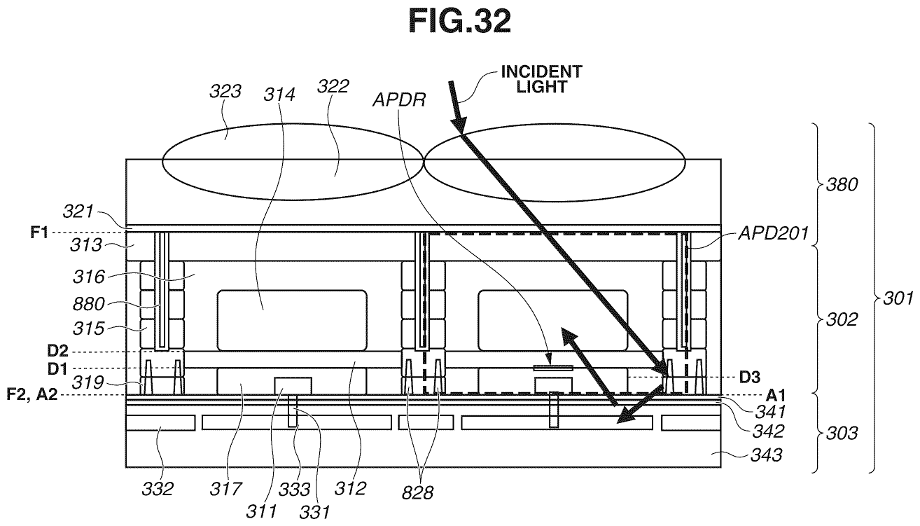

In the tenth exemplary embodiment, the trench portion 880 penetrates through the semiconductor layer 302. However, the trench portion 880 can also extend from the first surface F1 to a depth position in the middle of the semiconductor layer 302 as illustrated in FIG. 32. This configuration is a configuration in which an end portion on the side of the second surface F2 of the trench portion 880 is in contact with the semiconductor region in the semiconductor layer 302. With this configuration, the interval between two adjacent trench portions 828 can be reduced as compared with the configuration illustrated in FIG. 30. Thus, this configuration facilitates miniaturization of the pixel structure.

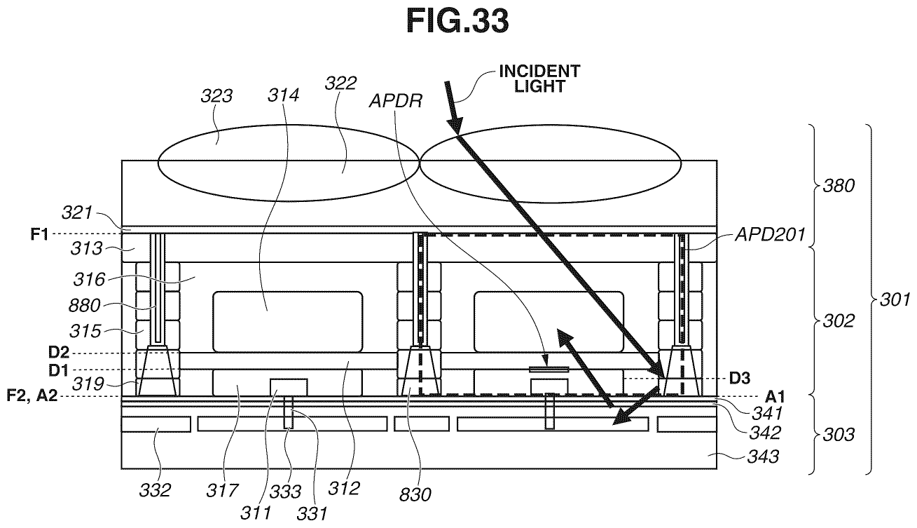

As illustrated in FIG. 33, the trench portion 880 and a trench portion 830 (a modified example of the dielectric material 344) extending from the second surface F2 can be connected in the semiconductor layer 302. In this configuration, the width of the trench portion 830 can be made greater than the width of the trench portion 880. This configuration can facilitate the reflection of incident light on the trench portion 830. Metal can also be embedded into the trench portion 830. In this case, the reflection of incident light can be enhanced as compared with a case where the inside of the trench portion 830 is filled with at least one of a silicon compound and air. Formation of the trench portion 830 with a tapered shape makes it possible to further enhance the reflection of incident light. An end portion on the side of the first surface F1 of the trench portion 830 is located at a position deeper than the depth position D2 as viewed from the second surface F2. However, the configuration of the trench portion 830 is not limited to this configuration, as long as the trench portion 830 includes a portion extending at a position deeper than at least the depth position D3.

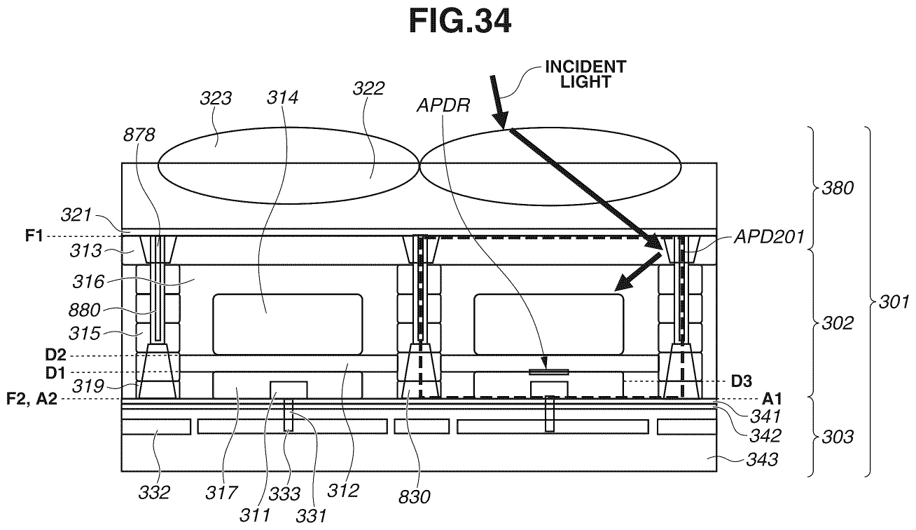

As illustrated in FIG. 34, a trench portion 878 extending from the first surface F1 can include a portion having a tapered shape. In this configuration, the portion having the tapered shape in the trench portion 878 is first formed as an STI structure. Thereafter, a DTI structure is formed into the semiconductor layer 302 from the bottom surface of the STI structure. The inside of the trench portion 878 can be filled with at least one of a silicon compound and air, can be filled with metal, or can be filled with vacuum. This structure makes it possible to suitably guide incident light into the APD, which leads to an improvement in sensitivity.

An eleventh exemplary embodiment will now be described centering on differences between the first exemplary embodiment.

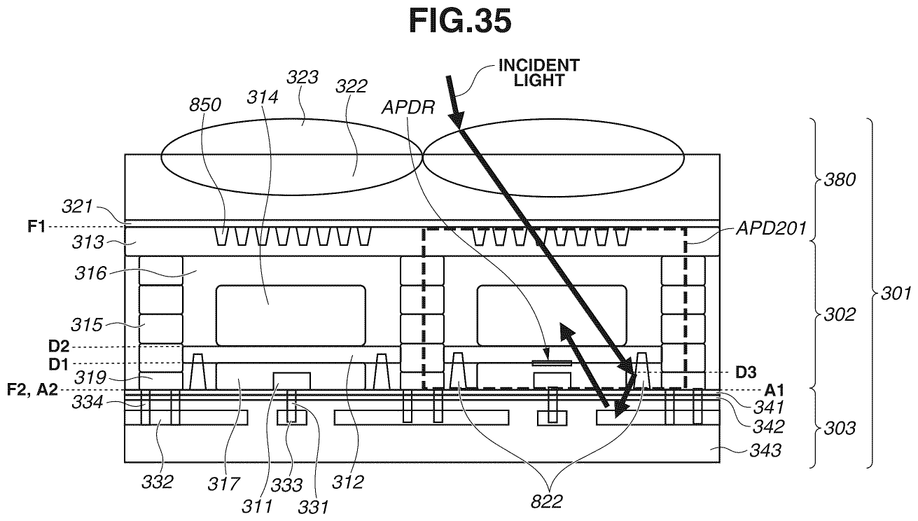

FIG. 35 is a sectional view of an APD according to the eleventh exemplary embodiment. A trench portion 822 corresponds to the dielectric material 344 according to the exemplary embodiments described above. In the eleventh exemplary embodiment, a diffraction structure 850 (formed of a dielectric material) is provided on the first surface F1 serving as the incidence surface of the APD. The diffraction structure 850 can be formed as an STI structure, or can be formed as a DTI structure.

The diffraction structure 850 can increase an optical path length from the incidence of light on the APD to photoelectric conversion. This can consequently improve the sensitivity of light with a long-wavelength band (in particular, near-infrared light).

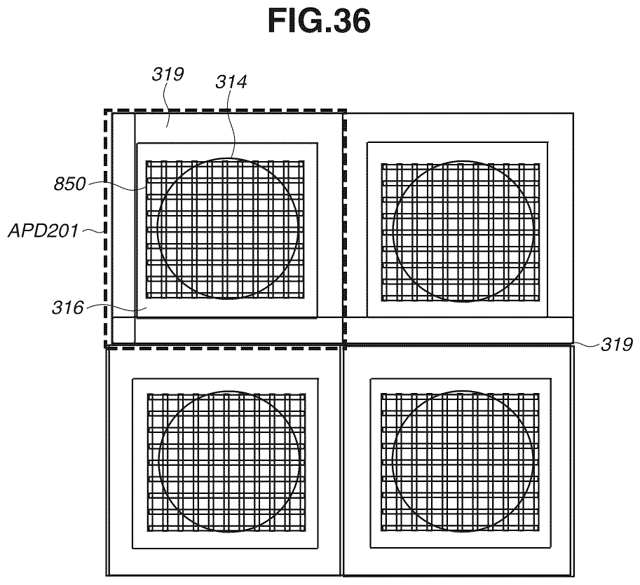

FIG. 36 is a plan view of the APD according to the eleventh exemplary embodiment with respect to the first surface F1. The diffraction structure 850 is provided in a lattice shape on the first surface F1. The lattice-shaped diffraction structure 850 is provided at a position overlapping the semiconductor region 314 in a planar view.

Thus, the APD according to the eleventh exemplary embodiment includes the dielectric material provided on the first surface F1 and the dielectric material provided on the second surface F2. This configuration further improves the sensitivity with respect to near-infrared light.

The eleventh exemplary embodiment can be combined with any of other exemplary embodiments.

In these exemplary embodiments, the interval between the dielectric materials provided on the first surface F1 is narrower than the interval between the dielectric materials provided on the second surface F2. This configuration enables the diffraction structure 850 to suitably diffract incident light.

The dielectric material 344 and modified examples of the dielectric material 344 have been described in the exemplary embodiments. The depth position of the end portion on the side of the first surface F1 of each of the dielectric material 344 and modified examples of the dielectric material 344 is not limited to the depth position in the configuration described in the exemplary embodiment, but instead can be modified to any depth position described in the other exemplary embodiments. Specifically, the depth position of the end portion on the side of the first surface F1 of each of the dielectric material 344 and modified examples of the dielectric material 344 is not particularly limited, as long as the dielectric material 344 is located at a position deeper than the depth position D3 at which the semiconductor region 319 is provided as viewed from the second surface F2. This configuration can reduce a leakage current between the anode region and the cathode region. The depth position of the end portion on the side of the first surface F1 of each of the dielectric material 344 and modified examples of the dielectric material 344 can be located between the depth position D2 and the depth position D1 at which the semiconductor region 312 is provided as viewed from the second surface F2. In this case, the leakage current can further be reduced. The depth position of the end portion on the side of the first surface F1 of each of the dielectric material 344 and modified examples of the dielectric material 344 can also be located at a position deeper than the depth position D2 at which the semiconductor region 312 is provided as viewed from the second surface F2. In this case, the leakage current can further be reduced.

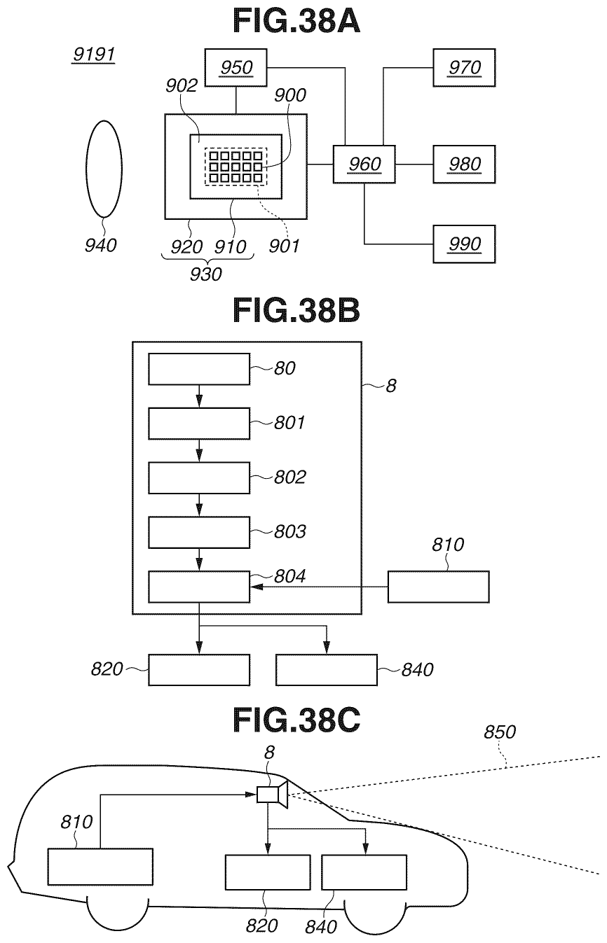

A twelfth exemplary embodiment is applicable to any one of the exemplary embodiments described above. FIG. 38A is a schematic diagram illustrating equipment 9191 including a semiconductor apparatus 930 according to the any one of the exemplary embodiments. The photoelectric conversion apparatus (image capturing apparatus) according to any one of the exemplary embodiments described above can be used as the semiconductor apparatus 930. The equipment 9191 including the semiconductor apparatus 930 will now be described in detail. As described above, the semiconductor apparatus 930 can include a semiconductor device 910 including a semiconductor layer 10, and a package 920 that accommodates the semiconductor device 910. The package 920 can include a base to which the semiconductor device 910 is fixed, and a lid that is made of glass or the like and is opposed to the semiconductor device 910. The package 920 can also include bonding members such as bonding wires and bumps for connecting terminals provided on the base with terminals provided on the semiconductor device 910.

The equipment 9191 can include at least any of an optical device 940, a control device 950, a processing device 960, a display device 970, a storage device 980, and a mechanical device 990. The optical device 940 corresponds to the semiconductor apparatus 930. The optical device 940 is, for example, a lens, a shutter, and a mirror. The control device 950 controls the semiconductor apparatus 930. The control device 950 is, for example, a semiconductor device such as an application-specific integrated circuit (ASIC) and the like.

The processing device 960 processes signals output from the semiconductor apparatus 930. The processing device 960 is a semiconductor device, such as a central processing unit (CPU) or an ASIC, for forming an analog front end (AFE) or a digital front end (DFE). The display device 970 is an electroluminescence (EL) display device or a liquid crystal display device that displays information (images) obtained by the semiconductor apparatus 930. The storage device 980 is a magnetic device or a semiconductor device that stores information (images) obtained by the semiconductor apparatus 930. The storage device 980 is a volatile memory such as a static random access memory (SRAM) or a dynamic RAM (DRAM), or a nonvolatile memory such as a flash memory or a hard disk drive.

The mechanical device 990 can include a movable unit or a propulsion unit such as a motor or an engine. The equipment 9191 displays a signal output from the semiconductor apparatus 930 on the display device 970, or transmits the signal to the outside with a communication device (not illustrated) included in the equipment 9191. The equipment 9191 can also preferably include the storage device 980 and the processing device 960 in addition to a storage circuit and an arithmetic circuit included in the semiconductor apparatus 930. The mechanical device 990 can be controlled based on a signal output from the semiconductor apparatus 930.

The equipment 9191 is suitable for electronic equipment such as an information terminal (e.g., a smartphone or a wearable terminal) having an image capturing function, and a camera (e.g., an interchangeable lens camera, a compact camera, a video camera, or a monitoring camera). The mechanical device 990 in a camera is configured to drive the components of the optical device 940 to perform zooming, an in-focus operation, and a shutter operation. Alternatively, the mechanical device 990 in a camera is configured to move the semiconductor apparatus 930 to perform an anti-vibration operation.

The equipment 9191 can be transportation equipment such as a vehicle, a vessel, or an airplane. The mechanical device 990 serving as transportation equipment can be used as a movable apparatus. The equipment 9191 serving as transportation equipment can be suitably used as equipment for transporting the semiconductor apparatus 930 or equipment that uses an image capturing function to assist and/or automate driving (steering). The processing device 960 for assisting and/or automating driving (steering) is configured to perform, based on the information obtained by the semiconductor apparatus 930, processing to operate the mechanical device 990 as a movable apparatus. Alternatively, the equipment 9191 can be medical equipment such as an endoscope, measurement equipment such as a range sensor, analysis equipment such as an electron microscope, office equipment such as a copying machine, or industrial equipment such as a robot.

According to the exemplary embodiments described above, it is possible to obtain excellent pixel characteristics. Thus, the value of the semiconductor apparatus can be increased. The aforementioned “increase in the value” corresponds to at least one of addition of a function, improvement of performance, improvement of characteristics, improvement of reliability, improvement of production yield, reduction of an environmental load, cost reduction, size reduction, and weight reduction.

The use of the semiconductor apparatus 930 according to the present exemplary embodiment for the equipment 9191 therefore makes it possible to improve the value of the equipment 9191. For example, the semiconductor apparatus 930 can be incorporated in transportation equipment so as to obtain an excellent performance when outside imaging of the transportation equipment is to be performed or when an external environment is to be measured. Hence, in the production and selling of transportation equipment, determining to incorporate the semiconductor apparatus 930 according to the present exemplary embodiment in transportation equipment is advantageous in enhancing the performance of the transportation equipment itself. In particular, the semiconductor apparatus 930 can be suitably used for transportation equipment that uses information obtained by the semiconductor apparatus 930 to perform driving assist and/or automated driving of the transportation equipment.

A photoelectric conversion system and a movable body according to the present exemplary embodiment will now be described with reference to FIGS. 38A to 38C.

FIG. 38B illustrates an example of a photoelectric conversion system for an in-vehicle camera. A photoelectric conversion system 8 includes a photoelectric conversion apparatus 80. The photoelectric conversion apparatus 80 is the photoelectric conversion apparatus (image capturing apparatus) according to any one of the exemplary embodiments described above. The photoelectric conversion system 8 includes an image processing unit 801 that performs image processing on a plurality of pieces of image data acquired by the photoelectric conversion apparatus 80, and a parallax acquisition unit 802 that calculates a parallax (a difference in phase between parallax images) based on the plurality of pieces of image data acquired by the photoelectric conversion system 8. The photoelectric conversion system 8 also includes a distance acquisition unit 803 that calculates a distance to a target object based on the calculated parallax, and a collision determination unit 804 that determines whether there is a possibility of collision based on the calculated distance. The parallax acquisition unit 802 and the distance acquisition unit 803 are examples of a distance information acquisition unit that acquires distance information about a distance to a target object. Specific examples of the distance information include information about a parallax, a defocusing amount, and a distance to a target object. The collision determination unit 804 can use any one of these pieces of information to determine whether there is a possibility of collision. The distance information acquisition unit can be implemented by exclusively designed hardware or can be implemented by a software module. Alternatively, the distance information acquisition unit can be implemented by a field programmable gate array (FPGA), an ASIC, and the like, or can be implemented by a combination of an FPGA, an ASIC, and the like.

The photoelectric conversion system 8 is connected to a vehicle information acquisition device 810 and is capable of acquiring vehicle information about a vehicle speed, a yaw rate, a steering angle, and the like of the vehicle. The photoelectric conversion system 8 is also connected to an electronic control unit (ECU) 820 serving as a control device that outputs, based on a determination result from the collision determination unit 804, a control signal to generate a braking force for the vehicle. The photoelectric conversion system 8 is also connected to an alarm device 830 that issues an alarm to a driver based on a determination result from the collision determination unit 804. For example, in a case where there is a high possibility of collision as a result of determination by the collision determination unit 804, the ECU 820 controls the vehicle to avoid the collision or reduce damage by, for example, applying a brake, releasing an accelerator, or suppressing an engine output. The alarm device 830 warns a user by, for example, sounding an alarm such as making a sound, displaying alarm information on a screen of a car navigation system or the like, giving a vibration to a seatbelt or a steering wheel.

In the present exemplary embodiment, the photoelectric conversion system 8 captures an image of surroundings of the vehicle, for example, the front side or the rear side of the vehicle.

FIG. 38C illustrates a configuration example of the photoelectric conversion system 8 that captures an image of the front side (image capturing range 850) of the vehicle. The vehicle information acquisition device 810 transmits an instruction to the photoelectric conversion system 8 or the photoelectric conversion apparatus 80. This configuration can improve the ranging accuracy.

The exemplary embodiment described above illustrates an example of control for preventing a vehicle from colliding with another vehicle. The exemplary embodiment can also be applied to, for example, control for automatic driving so as to follow other vehicles or control for automatic driving so as not to drive out of the lane. The exemplary embodiment can also be applied to a movable body (movable apparatus) such as a vessel, an airplane, or an industrial robot as well as vehicles such as automobiles. In addition, the exemplary embodiment can also be applied to a wide range of equipment using object recognition such as an intelligent transportation system (ITS) as well as movable bodies.

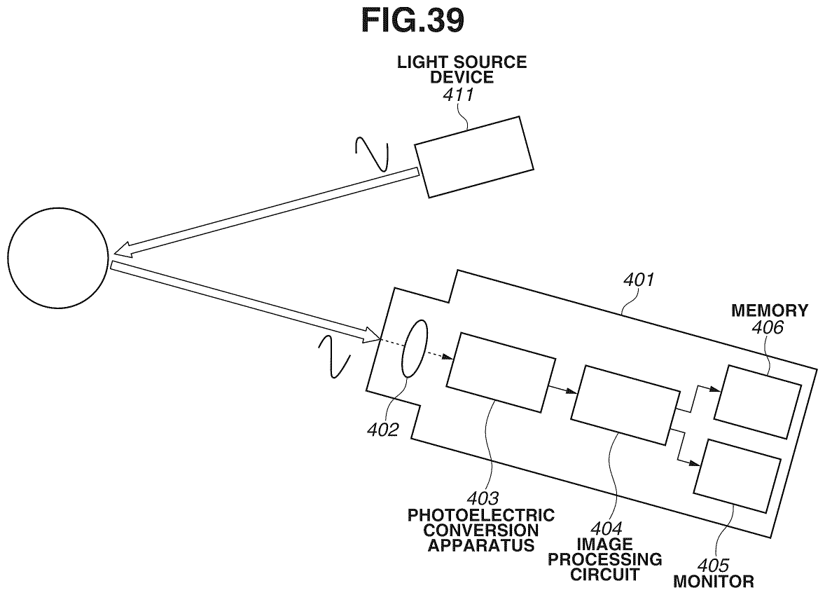

A photoelectric conversion system, which is sample equipment according to a thirteenth exemplary embodiment, will now be described with reference to FIG. 39. FIG. 39 is a block diagram illustrating a configuration example of a distance image sensor as an example of the photoelectric conversion system according to the thirteenth exemplary embodiment.

As illustrated in FIG. 39, a distance image sensor 401 includes an optical system 402, a photoelectric conversion apparatus 403, an image processing circuit 404, a monitor 405, and a memory 406. As the photoelectric conversion apparatus 403, the photoelectric conversion apparatus according to any one of the exemplary embodiments described above can be used. The distance image sensor 401 receives light (modulated light or pulsed light) that is emitted from a light source device 411 to an object and reflected on the surface of the object, thereby acquiring a distance image corresponding to a distance to the object.

The optical system 402 includes one or more lenses and is configured to guide image light (incident light) from the object to the photoelectric conversion apparatus 403 and forms an image on a light receiving surface (sensor portion) of the photoelectric conversion apparatus 403.

As the photoelectric conversion apparatus 403, the photoelectric conversion apparatus according to any one of the exemplary embodiments described above can be used. A distance signal indicating a distance obtained from a received optical signal output from the photoelectric conversion apparatus 403 is supplied to the image processing circuit 404.

The image processing circuit 404 performs image processing to generate a distance image based on the distance signal supplied from the photoelectric conversion apparatus 403. The distance image (image data) obtained by the image processing is supplied and displayed on the monitor 405, or is supplied and stored (recorded) in the memory 406.

In the distance image sensor 401 having such a configuration as described above, the pixel characteristics can be improved by applying any one of the photoelectric conversion apparatuses described above, and thereby a more accurate distance image can be acquired, for example.

The present disclosure is not limited to the above-described exemplary embodiments and can be modified in various ways.

For example, an example where a configuration described in any one of the exemplary embodiments is added to one or more of the other exemplary embodiments, and an example where a configuration described in any one of the exemplary embodiments is replaced with a configuration described in one or more of the other exemplary embodiments are included in the exemplary embodiments of the present disclosure.

The equipment described in the twelfth exemplary embodiment and the equipment described in the thirteenth exemplary embodiment are examples of the photoelectric conversion system to which the photoelectric conversion apparatus according to any one of the exemplary embodiments can be applied. The equipment and the photoelectric conversion system to which the photoelectric conversion apparatus according to any one of the exemplary embodiments can be applied are not limited to the configurations illustrated in FIGS. 38A to 38C and 39.

The above-described exemplary embodiments are merely specific examples for carrying out the present disclosure, and the technical scope of the present disclosure should not be interpreted in a limited way by the exemplary embodiments. That is, the present disclosure can be carried out in various forms without departing from the technical idea of the present disclosure or the principal features thereof.

The above-described exemplary embodiments can be modified as appropriate without departing from the technical idea of the present disclosure. The disclosed content of the present specification encompasses not only what is described in the present specification, but also all matters that can be recognized from the present specification and the drawings attached to the present specification. The disclosed content of the present specification includes complementary sets of concepts described in the present specification. In other words, if there is a description in the present specification to the effect that “A is larger than B”, for example, it can be said that the present specification discloses that “A is not larger than B” even if the description “A is not larger than B” is omitted. This is because the description “A is larger than B” is based on the premise that the case of “A is not larger than B” is taken into account.

According to an aspect of the present disclosure, it is possible to provide a technique for reducing a leakage current between an anode region and a cathode region of an APD.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-087054, filed May 29, 2024, which is hereby incorporated by reference herein in its entirety.

What is claimed is:

1. A photoelectric conversion apparatus comprising:
a semiconductor layer including an avalanche photodiode configured to perform an avalanche multiplication operation by a first voltage and a second voltage to be applied, and including a first surface on which light is incident and a second surface opposed to the first surface,
wherein the avalanche photodiode includes:
a first semiconductor region of a first conductivity type provided at a first depth position as viewed from the second surface in the semiconductor layer;
a second semiconductor region of a second conductivity type located closer to the second surface than the first semiconductor region;
a third semiconductor region of the first conductivity type located closer to the second surface than the second semiconductor region, in contact with a contact plug to which the first voltage is applied, and provided to a second depth position in depth from the second surface;
a region of a semiconductor region of the second conductivity type, in contact with a contact plug to which the second voltage is applied, and provided to a third depth position in depth from the second surface; and
a fourth semiconductor region of the first conductivity type provided between the region and the third semiconductor region,
wherein the photoelectric conversion apparatus includes a dielectric material including at least a portion extending from the second surface to an inside of the semiconductor layer, and being located on a portion overlapping at least the fourth semiconductor region in a planar view with respect to the second surface, and
wherein the portion extending from the second surface to an inside of the semiconductor layer extends over the third depth position from the second surface.

2. The photoelectric conversion apparatus according to claim 1, wherein an end portion of the dielectric material on a side of the first surface is located at a position deeper than the region in depth from the second surface.

3. The photoelectric conversion apparatus according to claim 2,
wherein the second semiconductor region is provided from a fourth depth position to a fifth depth position deeper than the fourth depth position as viewed from the second surface, and
wherein the end portion is located at a depth position between the fourth depth position and the fifth depth position.

4. The photoelectric conversion apparatus according to claim 2,
wherein the second semiconductor region is provided from the fourth depth position to a fifth depth position deeper than the fourth depth position as viewed from the second surface, and
wherein the end portion is located at a position deeper than the fifth depth position as viewed from the second surface.

5. The photoelectric conversion apparatus according to claim 1,
wherein the avalanche photodiode includes a fifth semiconductor region of the first conductivity type between the second semiconductor region and the third semiconductor region, and
wherein another dielectric material different from the dielectric material is located at a position overlapping at least the fourth semiconductor region in the planar view.

6. The photoelectric conversion apparatus according to claim 1, wherein the dielectric material is located at a position overlapping the region in the planar view.

7. The photoelectric conversion apparatus according to claim 1, wherein the avalanche photodiode includes a sixth semiconductor region of the second conductivity type along an inside surface of a trench in the dielectric material.

8. The photoelectric conversion apparatus according to claim 7, wherein an impurity concentration of the sixth semiconductor region is lower than an impurity concentration of the second semiconductor region.

9. The photoelectric conversion apparatus according to claim 1, wherein the photoelectric conversion apparatus includes a metallic member embedded in the semiconductor layer and the region is applied with the second voltage from the metallic member.

10. The photoelectric conversion apparatus according to claim 1, wherein the first voltage is a positive voltage and the second voltage is a negative voltage.

11. The photoelectric conversion apparatus according to claim 10, wherein the first conductivity type is n-type and the second conductivity type is p-type.

12. The photoelectric conversion apparatus according to claim 1,
wherein the photoelectric conversion apparatus has a structure of a plurality of substrates stacked,
wherein one of the plurality of substrates includes a wiring layer and the semiconductor layer,
wherein the second surface is located between the first surface and the wiring layer, and
wherein the one substrate and the other substrate are stacked.

13. The photoelectric conversion apparatus according to claim 2, wherein the end portion is in contact with the second semiconductor region.

14. A photoelectric conversion system comprising:
a photoelectric conversion apparatus including a semiconductor layer with an avalanche photodiode configured to perform an avalanche multiplication operation by a first voltage and a second voltage to be applied, and including a first surface on which light is incident and a second surface opposed to the first surface, wherein the avalanche photodiode comprises:
a first semiconductor region of a first conductivity type provided at a first depth position as viewed from the second surface in the semiconductor layer;
a second semiconductor region of a second conductivity type located closer to the second surface than the first semiconductor region;
a third semiconductor region of the first conductivity type located closer to the second surface than the second semiconductor region, in contact with a contact plug to which the first voltage is applied, and provided to a second depth position in depth from the second surface;
a region of a semiconductor region of the second conductivity type, in contact with a contact plug to which the second voltage is applied, and provided to a third depth position in depth from the second surface; and
a fourth semiconductor region of the first conductivity type provided between the region and the third semiconductor region,
wherein the photoelectric conversion apparatus includes a dielectric material including at least a portion extending from the second surface to an inside of the semiconductor layer, and being located on a portion overlapping at least the fourth semiconductor region in a planar view with respect to the second surface, and
wherein the portion extending from the second surface to an inside of the semiconductor layer extends over the third depth position from the second surface; and
a signal processing unit configured to generate an image using a signal output from the photoelectric conversion apparatus.

15. A movable body comprising:
a photoelectric conversion apparatus including a semiconductor layer with an avalanche photodiode configured to perform an avalanche multiplication operation by a first voltage and a second voltage to be applied, and including a first surface on which light is incident and a second surface opposed to the first surface, wherein the avalanche photodiode comprises:
a first semiconductor region of a first conductivity type provided at a first depth position as viewed from the second surface in the semiconductor layer;
a second semiconductor region of a second conductivity type located closer to the second surface than the first semiconductor region;
a third semiconductor region of the first conductivity type located closer to the second surface than the second semiconductor region, in contact with a contact plug to which the first voltage is applied, and provided to a second depth position in depth from the second surface;
a region of a semiconductor region of the second conductivity type, in contact with a contact plug to which the second voltage is applied, and provided to a third depth position in depth from the second surface; and
a fourth semiconductor region of the first conductivity type provided between the region and the third semiconductor region,
wherein the photoelectric conversion apparatus includes a dielectric material including at least a portion extending from the second surface to an inside of the semiconductor layer, and being located on a portion overlapping at least the fourth semiconductor region in a planar view with respect to the second surface, and
wherein the portion extending from the second surface to an inside of the semiconductor layer extends over the third depth position from the second surface; and
a control unit configured to control movement of the movable body using a signal output from the photoelectric conversion apparatus.

16. Equipment comprising the photoelectric conversion apparatus according to claim 1,
wherein the equipment further comprises at least any of:
an optical device corresponding to the photoelectric conversion apparatus;
a control device configured to control the photoelectric conversion apparatus;
a processing device configured to process a signal output from the photoelectric conversion apparatus;
a display device configured to display information obtained by the photoelectric conversion apparatus;
a storage device configured to store information obtained by the photoelectric conversion apparatus; and
a mechanical device configured to operate based on information obtained by the photoelectric conversion apparatus.
